(19) United States
(12) Patent Application Publication
(10) Pub. No.: US 2022/0250975 A1
(43) Pub. Date: Aug. 11, 2022

(54) GLASS-BASED ARTICLES WITH IMPROVED STRESS PROFILES

(71) Applicant: CORNING INCORPORATED, CORNING, NY (US)

(72) Inventors: Jennifer Lynn Hunt, CORNING, NY (US); Rostislav Vatchev Roussev, Painted Post, NY (US)

(21) Appl. No.: 17/623,778

(22) PCT Filed: Jul. 1, 2020
(86) PCT No.: PCT/US2020/040392

§ 371 Date: Dec. 29, 2021

Related U.S. Application Data
(60) Provisional application No. 62/869,898, filed on Jul. 2, 2019.

(51) Int. Cl. C03C 21/00; C03C 4/18; C03C 3/091; C03C 3/093; H05K 5/00; H05K 5/03

(52) U.S. Cl. CPC C03C 21/002; C03C 4/18; C03C 3/091; C03C 2204/00; H05K 5/0017; H05K 5/03; C03C 3/093

(57) ABSTRACT

Glass-based articles comprise: a lithium-based aluminosilicate composition; a glass-based substrate having opposing first and second surfaces defining a substrate thickness (t), wherein t is less than or equal to 0.74 mm; and a stress profile comprising: a spike region extending from the first surface and comprising a spike depth of layer (DOLₛₚ) located at a depth of greater than or equal to 7 micrometers; and a maximum central tension (CTₘₐₓ) of greater than or equal to 50 MPa.

### CROSS-REFERENCE TO RELATED APPLICATION

This application claims the benefit of priority under 35 U.S.C. § 119 of U.S. Provisional Application Ser. No. 62/869,898 filed on Jul. 2, 2019, the content of which is relied upon and incorporated herein by reference in its entirety.

### FIELD

Embodiments of the disclosure generally relate to glass-based articles having improved stress profiles and methods for manufacturing the same.

### BACKGROUND

Glass-based articles are used in many various industries including consumer electronics, transportation, architecture, defense, medical, and packaging. For consumer electronics, glass-based articles are used in electronic devices as cover plates or windows for portable or mobile electronic communication and entertainment devices, for example mobile phones, smart phones, tablets, watches, video players, information terminal (IT) devices, laptop computers, navigation systems and the like. In architecture, glass-based articles are included in windows, shower panels, and countertops; and in transportation, glass-based articles are present in automobiles, trains, aircraft, and sea-craft. Glass-based articles are suitable for any application that would benefit from superior fracture resistance but thin and light-weight articles. For each industry, mechanical and/or chemical reliability of the glass-based articles is typically driven by functionality, performance, and cost. Improving the mechanical and/or chemical reliability of these articles is an ongoing goal.

Chemical treatment is a strengthening method to impart a desired and/or engineered stress profile having one or more of the following parameters: compressive stress (CS), depth of compression (DOC), and maximum central tension (CT). Many glass-based articles, including those with engineered stress profiles, have a compressive stress that is highest or at a peak at the glass surface and reduces from a peak value moving away from the surface, and there is zero stress at some interior location of the glass article before the stress in the glass article becomes tensile. Chemical strengthening by ion exchange (IOX) of alkali-containing glass is a proven methodology in this field.

In the consumer electronics industry, chemically-strengthened glass is used as a preferred material for display covers due to better aesthetics and scratch resistance compared to plastics, and better drop performance plus better scratch resistance compared to non-strengthened glass.

There is an on-going need provide glass-based articles having mechanical and/or chemical reliability for their industry. There is also an ongoing need to do so in cost-effective ways.

### SUMMARY

Aspects of the disclosure pertain to glass-based articles and methods for their manufacture.

An aspect is a glass-based article comprising: a lithium-based aluminosilicate composition; a glass-based substrate having opposing first and second surfaces defining a substrate thickness (t), wherein t is less than or equal to 0.74 mm; and a stress profile comprising: a spike region extending from the first surface and comprising a spike depth of layer (DOLₛₚ) located at a depth of greater than or equal to 7 micrometers; and a maximum central tension (CTₘₐₓ) of greater than or equal to 50 MPa.

Another aspect is a glass-based article comprising: a lithium-based aluminosilicate composition; a glass-based substrate having opposing first and second surfaces defining a substrate thickness (t), wherein t is less than or equal to 0.74 mm; and a stress profile comprising: a spike region extending from the first surface and comprising a spike depth of layer (DOLₛₚ) located at a depth of greater than or equal 0.010·t; and a maximum central tension (CTₘₐₓ) of greater than or equal to 50 MPa.

A detailed aspect is a glass-based article comprising: a lithium-based aluminosilicate composition, wherein a molar ratio of Na₂O to Li₂O in the lithium-based aluminosilicate composition is less than or equal to 1.3; a glass-based substrate having opposing first and second surfaces defining a substrate thickness (t); and a stress profile comprising: a spike region extending from the first surface and comprising a spike depth of layer (DOLₛₚ) located at a depth of greater than or equal to 7 micrometers; and a maximum central tension (CTₘₐₓ) of greater than or equal to 50 MPa.

Another detailed aspect is a glass-based article comprising: a lithium-based aluminosilicate composition, wherein a molar ratio of Na₂O to Li₂O in the lithium-based aluminosilicate composition is less than or equal to 1.3; a glass-based substrate having opposing first and second surfaces defining a substrate thickness (t); and a stress profile comprising: a spike region extending from the first surface and comprising a spike depth of layer (DOLsp) located at a depth of greater than or equal 0.010·t; and a maximum central tension (CTmax) of greater than or equal to 50 MPa.

A further aspect is a consumer electronic product comprising: a housing having a front surface, a back surface, and side surfaces; electrical components provided at least partially within the housing, the electrical components including at least a controller, a memory, and a display, the display being provided at or adjacent the front surface of the housing; and a cover disposed over the display; wherein a portion of at least one of the housing and the cover comprises the glass-based article according to any aspect or embodiment disclosed herein.

In another aspect, a method of manufacturing a glass-based article comprises: exposing a glass-based substrate that comprises sodium oxide and lithium oxide in a base composition, the glass-based substrate having opposing first and second surfaces defining a substrate thickness (t), to an ion exchange treatment to form the glass-based article, the ion exchange treatment comprising: a first bath comprising a potassium salt and a sodium salt and a lithium salt; and a second bath comprising a potassium salt, a sodium salt, and optionally a lithium salt; wherein the one of the following is met: t is less than or equal to 0.74 mm; the substrate comprises a composition wherein a molar ratio of Na2O to Li2O in the lithium-based aluminosilicate composition is less than or equal to 1.3; or t is less than or equal to 0.74 mm and the substrate comprises a composition wherein a molar ratio of Na2O to Li2O in the lithium-based aluminosilicate composition is less than or equal to 1.3; wherein the glass-based article comprises a stress profile comprising: a spike region extending from the first surface and comprising a spike depth of layer (DOLsp) located at a depth of greater than or equal to 0.010·t; and a maximum central tension (CTmax) of greater than or equal to 50 MPa.

### BRIEF DESCRIPTION OF THE DRAWINGS

The accompanying figures, which are incorporated in and constitute a part of this specification, illustrate several embodiments described below.

FIG. 1A is a plan view of an exemplary electronic device incorporating any of the glass-based articles disclosed herein;

FIG. 1B is a perspective view of the exemplary electronic device of FIG. 1A;

FIG. 2 is a representative stress profile according to some embodiments disclosed herein;

FIG. 3 is a graph of spike depth of layer (DOLₛₚ) versus step 2 time (hrs.) according to some embodiments disclosed herein and a comparative;

FIG. 4 is a graph of central tension versus step 2 time (hrs.) according to some embodiments disclosed herein and a comparative;

FIG. 5 is a graph of maximum compressive stress (CSₘₐₓ) versus step 2 time (hrs.) according to some embodiments disclosed herein and a comparative;

FIG. 6 is a graph of spike depth of layer (DOLₛₚ) versus step 2 time (hrs.) according to some embodiments disclosed herein and a comparative;

FIG. 7 is a graph of central tension versus step 2 time (hrs.) according to some embodiments disclosed herein and a comparative;

FIG. 8 is a graph of maximum compressive stress (CSₘₐₓ) versus step 2 time (hrs.) according to some embodiments disclosed herein and a comparative;

FIG. 9 is a graph of spike depth of layer (DOLₛₚ) versus step 2 time (hrs.) according to some embodiments disclosed herein and a comparative;

FIG. 10 is a graph of central tension versus step 2 time (hrs.) according to some embodiments disclosed herein and a comparative;

FIG. 11 is a graph of maximum compressive stress (CSₘₐₓ) versus step 2 time (hrs.) according to some embodiments disclosed herein and a comparative;

FIG. 12 is a graph of spike depth of layer (DOLₛₚ) versus step 1 time (hrs.) for varying steps 2 and 3 according to some embodiments disclosed herein and a comparative;

FIG. 13 is a graph of central tension (CT) versus step 1 time (hrs.) for varying steps 2 and 3 according to some embodiments disclosed herein and a comparative;

FIG. 14 is a graph of maximum compressive stress (CSₘₐₓ, in MPa) versus step 1 time (hrs) according to some embodiments disclosed herein and a comparative;

FIGS. 15-16 are graphs of spike depth of layer (DOLₛₚ) for first step 1 time (hrs.) versus second step bath type according to some embodiments disclosed herein and a comparative;

FIG. 17 is a graph of central tension (CT) for a first step bath versus varied second step according to some embodiments disclosed herein and a comparative; and

FIGS. 18-19 are graphs of spike depth of layer (DOLₛₚ) for first step 1 time (hrs.) versus third step for differing first step bath types according to some embodiments disclosed herein and a comparative.

### DETAILED DESCRIPTION

Before describing several exemplary embodiments, it is to be understood that the disclosure is not limited to the details of construction or process steps set forth in the following disclosure. The disclosure provided herein is capable of other embodiments and of being practiced or being carried out in various ways.

Reference throughout this specification to “one embodiment,” “certain embodiments,” “various embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in various embodiments,” “in one embodiment” or “in an embodiment” in various places throughout this specification are not necessarily referring to the same embodiment. Furthermore, the particular features, structures, materials, or characteristics may be combined in any suitable manner in one or more embodiments.

### Definitions and Measurement Techniques

The terms “glass-based article” and “glass-based substrates” are used to include any object made wholly or partly of glass, including glass-ceramics (including an amorphous phase and a crystalline phase). Laminated glass-based articles include laminates of glass and non-glass materials, for example laminates of glass and crystalline materials. Glass-based substrates according to one or more embodiments can be selected from alkali-aluminosilicate glass, alkali-containing borosilicate glass, alkali-containing aluminoborosilicate glass, and alkali-containing phosphosilicate glass.

A “base composition” is a chemical make-up of a substrate prior to any ion exchange (IOX) treatment. That is, the base composition is undoped by any ions from IOX. A composition at the center of a glass-based article that has been IOX treated is typically the same as the base composition when IOX treatment conditions are such that ions supplied for IOX do not diffuse into the center of the substrate. In one or more embodiments, a composition at the center of the glass article comprises the base composition.

Reference to “in chemical equilibrium” means that any diffusion of two or more alkali ions of the base composition of the substrate or the central composition of the article is less than about 10% into the IOX bath.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue. Thus, for example, a glass-based article that is “substantially free of MgO” is one in which MgO is not actively added or batched into the glass-based article, but may be present in very small amounts as a contaminant, for example amounts less than 0.01 mol %. As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” For example, “about 10 mol %” is intended to disclosed the about modified value and the value of exactly 10 mol %. It will be further understood that the endpoints of each of the ranges are significant both in relation to the other endpoint, and independently of the other endpoint.

Unless otherwise specified, all compositions described herein are expressed in terms of mole percent (mol %) on an oxide basis.

A “stress profile” is stress with respect to position of a glass-based article or any portion thereof. A compressive stress region extends from a first surface to a depth of compression (DOC) of the article, where the article is under compressive stress. A central tension region extends from the DOC to include the region where the article is under tensile stress.

As used herein, depth of compression (DOC) refers to the depth at which the stress within the glass-based article changes from compressive to tensile stress. At the DOC, the stress crosses from a positive (compressive) stress to a negative (tensile) stress and thus exhibits a stress value of zero. According to the convention normally used in mechanical arts, compression is expressed as a negative (<0) stress and tension is expressed as a positive (>0) stress. Throughout this description, however, compressive stress (CS) is expressed as a positive or absolute value—i.e., as recited herein, CS=|CS|. When used with the term “tensile”, stress or central tension (CT) may be expressed as a positive value, i.e., CT=|CT| Central tension (CT) refers to tensile stress in a central region or central tension region of the glass-based article. Maximum central tension (maximum CT or CTₘₐₓ) occurs in the central tension region nominally at 0.5·t, where t is the article thickness, which allows for variation from exact center of the location of the maximum tensile stress. Peak tension (PT) refers to maximum tension measured, which may or may not be at the center of the article.

A “knee” of a stress profile is a depth of an article where the slope of the stress profile transitions from steep to gradual.

A non-zero metal oxide concentration that varies from the first surface to a depth of layer (DOL) with respect to the metal oxide or that varies along at least a substantial portion of the article thickness (t) indicates that a stress has been generated in the article as a result of ion exchange. The variation in metal oxide concentration may be referred to herein as a metal oxide concentration gradient. The metal oxide that is non-zero in concentration and varies from the first surface to a DOL or along a portion of the thickness may be described as generating a stress in the glass-based article. The concentration gradient or variation of metal oxides is created by chemically strengthening a glass-based substrate in which a plurality of first metal ions in the glass-based substrate is exchanged with a plurality of second metal ions.

As used herein, the terms “depth of exchange”, “depth of layer” (DOL), “chemical depth of layer”, and “depth of chemical layer” may be used interchangeably, describing in general the depth at which ion exchange facilitated by an ion exchange process (IOX) takes place for a particular ion. DOL refers to the depth within a glass-based article (i.e., the distance from a surface of the glass-based article to its interior region) at which an ion of a metal oxide or alkali metal oxide (e.g., the metal ion or alkali metal ion) diffuses into the glass-based article where the concentration of the ion reaches a minimum value, or a value substantially similar to that in the base glass composition, as determined by Glow Discharge-Optical Emission Spectroscopy (GD-OES)). In some embodiments, the DOL is given as the depth of exchange of the slowest-diffusing or largest ion introduced by an ion exchange (IOX) process. DOL with respect to potassium (DOL_{K}) is the depth at which the potassium content of the glass article reaches the potassium content of the underlying substrate. Spike depth of layer of (DOLₛₚ) where knee stress (CSₖ) is located is measured by an FSM prism coupler. DOLₛₚ is approximately the same as DOL_{K}.

Unless otherwise specified, CT and CS are expressed herein in MegaPascals (MPa), thickness is express in millimeters (mm) and DOC and DOL are expressed in microns (micrometers, or μm).

Compressive stress (including surface and/or peak CS, CSₘₐₓ) and DOLₛₚ are measured by surface stress meter (FSM) using commercially available instruments for example the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety.

Compressive stress at the knee CSₖ may be measured by a method according to U.S. Ser. No. 16/015,776, filed Jun. 22, 2018 to the assignee, which is incorporated herein by reference.

The maximum central tension (CT) or peak tension (PT) and stress retention values are measured using a scattered light polariscope (SCALP) technique known in the art. The Refracted near-field (RNF) method or SCALP may be used to measure the stress profile and the depth of compression (DOC). When the RNF method is utilized to measure the stress profile, the maximum CT value provided by SCALP is utilized in the RNF method. In particular, the stress profile measured by RNF is force balanced and calibrated to the maximum CT value provided by a SCALP measurement. The RNF method is described in U.S. Pat. No. 8,854,623, entitled “Systems and methods for measuring a profile characteristic of a glass sample”, which is incorporated herein by reference in its entirety.

### General Overview of Properties of Glass-Based Articles

Disclosed herein are lithium (Li)-containing glass-based articles of thickness t having improved stress profiles with excellent spike depth, as measured by depth of layer of potassium (DOL_{K}), in combination with a large maximum compressive stress (CSₘₐₓ), large depth of compression (DOC), good knee compressive stress (CSₖ), and good central tension (CT). In particular, advantageous stress profiles for thin Li-containing glass articles have an increased spike depth (DOL_{K} of greater than or equal to 7) in combination with one or any combination of the following: CSₘₐₓ of greater than or equal to 400 MPa, including greater than or equal to 500 MPa, greater than or equal to 550 MPa, greater than or equal to 600 MPa, greater than or equal to 650 MPa, and greater than or equal to 700 MPa; DOC of greater than or equal to 0.16·t, CSₖ of greater than or equal to 90 MPa, wherein t is greater than or equal to 0.2 millimeters and/or less than or equal to 1.3 millimeters, including all values and ranges therebetween, including 0.65 mm, 0.6 mm, 0.5 mm, 0.4 mm, and 0.3 mm. Glass-based articles herein provide good resistance to fracture against several failure modes, including deep damage introduction, flexure overstress on the large surfaces (for example in ball-drop testing), and edge overstress.

Usually in lithium-based glass-based substrates, two ions, sodium (Na) and potassium (K), are used for diffusion and formation of a stress profile. K being an ion with larger ionic radius induces higher stress but is slow to diffuse in comparison the smaller ionic radius Na ion that induces lower stress but diffuses faster. The K ions define what is called the spike of the profile and the Na ions the deep tail of the profile. After this point, further diffusion will lead to increase of K diffusion and the depth of the spike (known as DOL of the spike), but at the expense of modifying the ion content in the middle of the sample and further reducing tensile stress in the nominal center of the sample known as the center tension (CT). Longer diffusion times also lead to further reduction of other areas of the stress profile, as is the case of the region where the spike and the tail of the stress profile meet known as the stress at the knee (CSₖ).

Lithium-containing glass-based articles have shown advantages for obtaining stress profiles with very large depth of compression by ion-exchange (chemical) strengthening compared to Li-free glasses. Profiles with large depth of compression and adequate surface compressive stress can sometimes result in limitations, for example, trade-offs with respect to knee stress (CSₖ) and/or central tension. In particular, achieving an adequate spike depth of layer (DOLₛₚ), for example, greater than or equal to 7.5 micrometers, takes longer than the time for Na to diffuse from the surface into a depth of the substrate. As a result, the deep portion of the stress profile is fully developed (DOC is already substantially maximized) before a desired DOLₛₚ is obtained, and additional ion exchange designed to increase the DOLₛₚ does not bring about substantial DOC increase, and can actually lead to an undesired effect of reduction in CSₖ. This is challenging further when both a large DOLₛₚ, a large CS, for example, greater than or equal to 750 MPa, are sought. These challenges can occur specifically when the Li-containing glasses are of small thickness, for example less than or equal to 0.8 mm, or less than or equal to 0.74, or less than or equal to 7.0, and in particular less than or equal to 0.65 mm, for example less than or equal to 0.6 mm, or less than or equal to 0.55 mm, or less than or equal to 0.50 mm, or less than or equal to 0.45 mm, or less than or equal to 0.40 mm, or less than or equal to 0.35 mm; and/or when the Li-containing glasses have base compositions having molar ratios of Na₂O to Li₂O of less than or equal to 1; and/or when the base compositions have no significant concentration of K₂O, including when the base K₂O concentration is less than or equal to 7% of the total alkali content, and/or less than or equal to about 1.4 mol % of the base composition, and in particular when the base concentration of K₂O is less than 1.3 mol %, or is less than 1.2 mol %, or is less than 1.1 mol %, or is less than 1.0 mol %, or is less than 0.9 mol %, or is less than 0.8 mol %, or is less than 0.7 mol %, or is less than 0.6 mol %, or is less than 0.5 mol %, or less than 0.45 mol %, or less than 0.40 mol %, or less than 0.35 mol %, or less than 0.30 mol %.

In one or more embodiments, glass-based articles comprise a DOLₛₚ of greater than or equal to 7 micrometers to less than or equal to 20 micrometers, including all values and subranges therebetween, for example from greater than or equal to 7.5 micrometers to less than or equal to 15 micrometers, or from greater than or equal to 8 micrometers to less than or equal to 15 micrometers, or from greater than or equal to 8 micrometers to less than or equal to 15 micrometers, or from greater than or equal to 8.5 micrometers to less than or equal to 14.5 micrometers, or from greater than or equal to 9 micrometers to less than or equal to 14 micrometers, or from greater than or equal to 9.5 micrometers to less than or equal to 13.5 micrometers, or from greater than or equal to 10 micrometers to less than or equal to 13 micrometers, or from greater than or equal to 10.5 micrometers to less than or equal to 12.5 micrometers, or from greater than or equal to 11 micrometers to less than or equal to 12 micrometers.

In one or more embodiments, glass-based articles comprise a DOLₛₚ of greater than or equal to 0.010·t, or greater than or equal to 0.0125·t, or greater than or equal to 0.015·t, or greater than or equal to 0.0175·t, or greater than or equal to 0.020·t, or greater than or equal to 0.025·t, and/or less than or equal to 0.050·t, and all values and subranges therebetween.

In one or more embodiments, glass-based articles comprise a DOLₛₚ of greater than or equal to 7 micrometers to less than or equal to 20 micrometers, including any and all values and sub-ranges therebetween, for example from greater than or equal to 7.5 micrometers to less than or equal to 15 micrometers, and greater than or equal to 8 micrometers to less than or equal to 15 micrometers; and one or a combination of the following features: a thickness of greater than or equal to 0.02 millimeters to less than or equal to 1.3 millimeters, for example from greater than or equal to 0.05 millimeters to less than or equal to 1 millimeters, including less than or equal to 0.8 millimeters, 0.74, or less than or equal to 7.0, and in particular less than or equal to 0.65 mm, for example less than or equal to 0.6 mm, or less than or equal to 0.55 mm, or less than or equal to 0.50 mm, or less than or equal to 0.45 mm, or less than or equal to 0.40 mm, or less than or equal to 0.35 mm; a knee compressive stress (CSₖ) of greater than or equal to 85 MPa, including and greater than or equal to 90 MPa; and/or a central tension (CT) of greater than or equal to 60 MPa; and/or a maximum compressive stress (CSₘₐₓ) of greater than or equal to 400 MPa, for example greater than or equal to 450 MPa, greater than or equal to 500 MPa, greater than or equal to 550 MPa, greater than or equal to 600 MPa, greater than or equal to 650 MPa, greater than or equal to 700 MPa, greater than or equal to 750 MPa; and/or a depth of compression (DOC) of greater than or equal to 0.16·t; and/or a base composition comprising a molar ratio of Na₂O to Li₂O of less than or equal to 1.3 and greater than or equal to 0.16, for example less than or equal to 1.2, or less than or equal to 1.1, or less than or equal to 1.0, or less than or equal to 0.9, or less than or equal to 0.8, or less than or equal to 0.7, or less than or equal to 0.6, or less than or equal to 0.5, or less than or equal to 0.4, or less than or equal to 0.3, including all values and subranges therebetween, including 0.63 and 0.29.

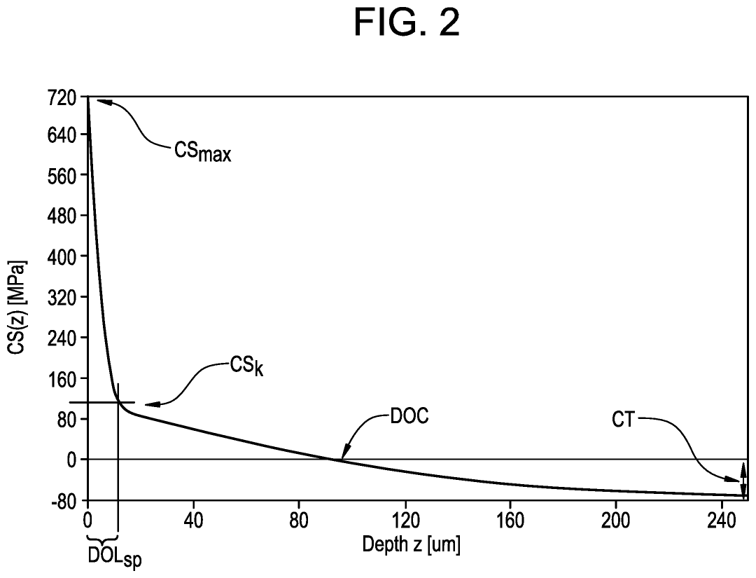

The present disclosure uses a process for enriching a near-surface layer of the glass article with potassium ion (K) while developing a deep portion of the stress profile. FIG. 2 provides a non-limiting representative modeled stress profile for one-half of an article thickness according to some embodiments disclosed herein made in accordance with methods disclosed herein (Example 29 discussed herein). In FIG. 2, thickness of 500 micrometers, a maximum compressive stress (CSₘₐₓ) was about 717 MPa, the compressive stress at the knee (CSₖ) was in the range of from about 110 to about 120 MPa, the spike depth of layer (DOLₛₚ) was about 10.7 micrometers (0.02144), the depth of compression (DOC) was in the range of from about 89 to about 94 micrometers (0.19·t), and the central tension (CT) was in the range of from about 64 to about 70 MPa. A spike region extended from surface (0 micrometers) to the DOLₛₚ. It can be difficult to pinpoint a particular asymptotic point where the transition between the spike and tail of the profile occurs, but in general all points of the stress profile located in the spike region comprise a tangent having a slope with an absolute value that is 20 MPa/micrometer or greater, and all points of the stress profile located in the tail region comprise a tangent having a slope with an absolute value that is less than the absolute values of the slopes of the tangents of the spike region, for example less than 20 MPa/micrometer, or less than 15 MPa/micrometer, or less than 10 MPa/micrometer, or less than 5 MPa/micrometer, or less than 4 MPa/micrometer, or less than 3 MPa/micrometer, or less than 2 MPa/micrometer.

In these processes, a first step of a multistep ion exchange treatment creates a significant spike region in the surface of the glass plus a decaying tail of the stress profile towards the center of the article. A second step forms the tail region of the stress profile without disrupting the spike region. The methods herein are in an opposite order compared to previous two-step ion exchange processes (or double ion exchange processes, or DIOX), which typically rely on a first step to create a deeper portion of a stress profile within the substrate using, for example, by using for example a bath of: 50 wt % KNO₃/50 wt % NaNO₃ (380° C. for 4 hours) followed by a second step to impart a spike near the surface using, for example, a bath of: 90 wt % KNO₃/10 wt % NaNO₃ (20 minutes).

The stress profiles achieved by the methods disclosed herein are advantageous in that deep values of DOLₛₚ are achieved for thin articles. And it is believed that deep values of DOLₛₚ and/or high values of CSₖ are beneficial in achieving greater drop performance of glass-based articles.

Stress profiles may comprise: a spike region extending from the first surface to a tail region; and a tail region extending to a center of the glass-based article; wherein all points of the stress profile located in the spike region comprise a tangent having a slope with an absolute value that is 20 MPa/micrometer or greater, and all points of the stress profile located in the tail region comprise a tangent having a slope with an absolute value that is less than the absolute values of the slopes of the tangents of the spike region.

In the glass-based articles, there is a metal oxide having a non-zero concentration that varies from the first surface to a depth of layer (DOL) with respect to the metal oxide. In one or more embodiments, the metal oxide having a non-zero concentration that varies from the first surface is potassium, having a DOL_{K}. A stress profile is generated due to the non-zero concentration of the metal oxide(s) that varies from the first surface. The non-zero concentration may vary along a portion of the article thickness. In some embodiments, the concentration of the metal oxide is non-zero and varies, along a thickness range from 0·t to about 0.3·t. In some embodiments, the concentration of the metal oxide, for example potassium, is non-zero and varies along a thickness range from 0·t to about 0.050·t, or from 0·t to about 0.0.25·t, or from 0·t to about 0.020·t, or from 0·t to about 0.0175·t, or from 0·t to about 0.015·t, or from 0·t to about 0.0125·t, or from 0·t to about 0.010·t. In some embodiments the variation in concentration may be continuous along the above-referenced thickness ranges. Variation in concentration may include a change in metal oxide concentration of at least about 0.2 mol % from the surface to the DOL, for example DOL_{K}. In some embodiments the change in metal oxide concentration may be at least about 0.3 mol %, or at least about 0.4 mol %, or at least about 0.5 mol % from the surface to the DOL, for example DOL_{K}. This change may be measured by known methods in the art including microprobe.

In some embodiments, the variation in concentration may be continuous along thickness segments in the range from about 10 micrometers to about 30 micrometers. In some embodiments, the concentration of the metal oxide decreases from the first surface to a value at a point between the first surface and the second surface and increases from that value to the second surface.

The concentration of metal oxide may include more than one metal oxide (e.g., a combination of Na₂O and K₂O). In some embodiments, where two metal oxides are utilized and where the radius of the ions differ from one or another, the concentration of ions having a larger radius is greater than the concentration of ions having a smaller radius at shallow depths, while at deeper depths, the concentration of ions having a smaller radius is greater than the concentration of ions having larger radius. For example, where a single Na- and K-containing bath is used in the ion exchange process, the concentration of K+ ions in the glass-based article is greater than the concentration of Na+ ions at shallower depths, while the concentration of Na+ is greater than the concentration of K+ ions at deeper depths. This is due, in part, to the size of the monovalent ions that are exchanged into the glass for smaller monovalent ions. In such glass-based articles, the area at or near the surface comprises a greater CS due to the greater amount of larger ions (for example, K+ ions) at or near the surface. Furthermore, the slope of the stress profile typically decreases with distance from the surface due to the nature of the concentration profile achieved due to chemical diffusion from a fixed surface concentration.

In one or more embodiments, the metal oxide concentration gradient extends through a substantial portion of the thickness t of the article. In some embodiments, the concentration of the metal oxide may be about 0.5 mol % or greater (e.g., about 1 mol % or greater) along the entire thickness of the first and/or second section, and is greatest at a first surface and/or a second surface 0·t and decreases substantially constantly to a value at a point between the first and second surfaces. At that point, the concentration of the metal oxide is the least along the entire thickness t; however the concentration may also be non-zero at that point. In other words, the non-zero concentration of that particular metal oxide extends along a substantial portion of the thickness t (as described herein) or the entire thickness t. The total concentration of the particular metal oxide in the glass-based article may be in the range from about 1 mol % to about 20 mol %.

The concentration of the metal oxide may be determined from a baseline amount of the metal oxide in the glass-based substrate that is ion exchanged to form the glass-based article.

In one or more embodiments, the glass-based articles comprise a depth of compression (DOC) of greater than or equal to 0.16·t, including greater than or equal to 0.17·t, greater than or equal to 0.18·t, greater than or equal to 0.19·t, greater than or equal to 0.20·t, greater than or equal to 0.21·t, greater than or equal to 0.22·t, greater than or equal to 0.23·t, greater than or equal to 0.24·t, or deeper.

In one or more embodiments, all points of the stress profile located in the spike region comprise a tangent having a slope with an absolute value that is 20 MPa/micrometer or greater.

In one or more embodiments, the glass-based articles comprise a maximum compressive stress (CSₘₐₓ, nominally at the first surface) that may be greater than or equal to 400 MPa. For example, CSₘₐₓ may be greater than or equal to 450 MPa and less than or equal to 1200 MPa, greater than or equal to 500 MPa to less than or equal to 1100 MPa, greater than or equal to 550 MPa to less than or equal to 1050 MPa, greater than or equal to 600 MPa to less than or equal to 1000 MPa, greater than or equal to 650 MPa to less than or equal to 950 MPa, greater than or equal to 700 MPa to less than or equal to 950 MPa, greater than or equal to 700 MPa to less than or equal to 900 MPa, greater than or equal to 700 MPa to less than or equal to 850 MPa, greater than or equal to 700 MPa to less than or equal to 800 MPa, or about 750 MPa, and all values and subranges therebetween.

In one or more embodiments, the glass-based articles comprise a spike depth of layer (DOLₛₚ) with respect to thickness may be greater than or equal to 0.010·t, including greater than or equal to 0.0125·t, greater than or equal to 0.015·t, greater than or equal to 0.0175·t, greater than or equal to 0.020·t, greater than or equal to 0.0215·t, or deeper.

In one or more embodiments, the glass-based articles comprise a thickness of greater than or equal to 0.02 millimeters to less than or equal to 1.3 millimeters, greater than or equal to 0.05 millimeters to less than or equal to 1 millimeters, including less than or equal to 0.8 millimeters, 0.74, or less than or equal to 7.0, and in particular less than or equal to 0.65 mm, for example less than or equal to 0.6 mm, or less than or equal to 0.55 mm, or less than or equal to 0.50 mm, or less than or equal to 0.45 mm, or less than or equal to 0.40 mm, or less than or equal to 0.35 mm.

In one or more embodiments, the glass-based articles comprise a knee compressive stress (CSₖ) of greater than or equal to 70 MPa to less than or equal to 180 MPa, including all values and subranges therebetween, including greater than or equal to 75 MPa, greater than or equal to 80 MPa, greater than or equal to 85 MPa, greater than or equal to 90 MPa, or greater than or equal to 95 MPa, or greater than or equal to 100 MPa, or greater than or equal to 110 MPa, or greater than or equal to 120 MPa, or greater than or equal to 125 MPa, or greater than or equal to 130 MPa, or greater than or equal to 135 MPa, or greater than or equal to 140 MPa, or greater than or equal to 145 MPa, greater than or equal to 150 MPa, greater than or equal to 155 MPa, greater than or equal to 160 MPa, greater than or equal to 165 MPa, greater than or equal to 170 MPa, or greater than or equal to 175 MPa.

In one or more embodiments, the glass-based articles comprise a central tension (CT, or CTₘₐₓ) of greater than or equal to 50 MPa to less than or equal to 120 MPa, including all values and subranges therebetween, including greater than or equal to 52 MPa, or greater than or equal to 55 MPa, or greater than or equal to 60 MPa, or greater than or equal to 65 MPa, or greater than or equal to 70 MPa, or greater than or equal to 75 MPa, or greater than or equal to 80 MPa, or greater than or equal to 85 MPa, or greater than or equal to 90 MPa, or greater than or equal to 100 MPa, or greater than or equal to 115 MPa.

In one or more embodiments, the glass-based articles comprise a base composition having a molar ratio of Na₂O to Li₂O of less than or equal to 1.3 and greater than or equal to 0.16, for example less than or equal to 1.2, or less than or equal to 1.1, or less than or equal to 1.0, or less than or equal to 0.9, or less than or equal to 0.8, or less than or equal to 0.7, or less than or equal to 0.6, or less than or equal to 0.5, or less than or equal to 0.4, or less than or equal to 0.3, including all values and subranges therebetween, including 0.63 and 0.29.

In one or more embodiments, the glass-based articles comprise a base composition having a molar ratio of Na₂O to Li₂O of less than or equal to 1.3 and greater than or equal to 0.16, for example less than or equal to 1.2, or less than or equal to 1.1, or less than or equal to 1.0, or less than or equal to 0.9, or less than or equal to 0.8, or less than or equal to 0.7, or less than or equal to 0.6, or less than or equal to 0.5, or less than or equal to 0.4, or less than or equal to 0.3, including all values and subranges therebetween, including 0.63 and 0.29.

In one or more embodiments, the glass-based articles comprise a concentration of Li₂O on the surface of greater than or equal to 0.6 mol %, or greater than or equal to 1 mol %, or greater than or equal to 1.4 mol %.

In one or more embodiments, the glass-based articles comprise a concentration of Li₂O on the surface of greater than or equal to 0.6 mol %, or greater than or equal to 1 mol %, or greater than or equal to 1.4 mol % in combination with a knee compressive stress (CSₖ) of greater than or equal to 70 MPa to less than or equal to 100 MPa, including all values and subranges therebetween.

### Glass-Based Substrates

Examples of glasses that may be used as substrates may include alkali-alumino silicate glass compositions or alkali-containing aluminoborosilicate glass compositions, though other glass compositions are contemplated. Such glass compositions may be characterized as ion exchangeable. As used herein, “ion exchangeable” means that a substrate comprising the composition is capable of exchanging cations located at or near the surface of the substrate with cations of the same valence that are either larger or smaller in size.

In some embodiments, the substrates may comprise a lithium-containing alkali aluminosilicate glass. In some embodiments, the lithium-containing alkali aluminosilicate glass has a composition including, in mol %, SiO₂ in an amount in the range from about 60% to about 75%, Al₂O₃ in an amount in the range from about 12% to about 20%, B₂O₃ in an amount in the range from about 0% to about 5%, Li₂O in an amount in the range from about 2% to about 8%, Na₂O in an amount greater than about 4%, MgO in an amount in the range from about 0% to about 5%, ZnO in an amount in the range from about 0% to about 3%, CaO in an amount in the range from about 0% to about 5%, and P₂O₅ in a non-zero amount; wherein the glass substrate is ion-exchangeable and is amorphous, wherein the total amount of Al₂O₃ and Na₂O in the composition is greater than about 15 mol %.

In embodiments, the glass-based substrates may be formed from any composition capable of forming the stress profiles. In some embodiments, the glass-based substrates may be formed from the glass compositions described in U.S. application Ser. No. 16/202,691 titled “Glasses with Low Excess Modifier Content,” filed Nov. 28, 2018, the entirety of which is incorporated herein by reference. In some embodiments, the glass articles may be formed from the glass compositions described in U.S. application Ser. No. 16/202,767 titled “Ion-Exchangeable Mixed Alkali Aluminosilicate Glasses,” filed Nov. 28, 2018, the entirety of which is incorporated herein by reference.

The glass-based substrates may be characterized by the manner in which it may be formed. For instance, the glass-based substrates may be characterized as float-formable (i.e., formed by a float process), down-drawable and, in particular, fusion-formable or slot-drawable (i.e., formed by a down draw process for example a fusion draw process or a slot draw process). In embodiments, the glass-based substrates may be roll formed.

A glass-based substrate may be prepared by floating molten glass on a bed of molten metal, typically tin to produce a float glass characterized by smooth surfaces and uniform thickness. In an example process, molten glass that is fed onto the surface of the molten tin bed forms a floating glass ribbon. As the glass ribbon flows along the tin bath, the temperature is gradually decreased until the glass ribbon solidifies into a solid glass-based substrate that can be lifted from the tin onto rollers. Once off the bath, the glass-based substrate can be cooled further, annealed to reduce internal stress, and optionally polished.

Some embodiments of the glass-based substrates described herein may be formed by a down-draw process. Down-draw processes produce glass-based substrates having a uniform thickness that possess relatively pristine surfaces. Because the average flexural strength of the glass article is controlled by the amount and size of surface flaws, a pristine surface that has had minimal contact has a higher initial strength. Down-drawn glass-based substrates may be drawn to a thickness of less than about 2 mm. In addition, down drawn glass articles have a very flat, smooth surface that can be used in its final application without costly grinding and polishing.

Some embodiments of the glass-based substrates may be described as fusion-formable (i.e., formable using a fusion draw process). The fusion process uses a drawing tank that has a channel for accepting molten glass raw material. The channel has weirs that are open at the top along the length of the channel on both sides of the channel. When the channel fills with molten material, the molten glass overflows the weirs. Due to gravity, the molten glass flows down the outside surfaces of the drawing tank as two flowing glass films. These outside surfaces of the drawing tank extend down and inwardly so that they join at an edge below the drawing tank. The two flowing glass films join at this edge to fuse and form a single flowing glass article, which includes a fusion line at or near the center of the article and that can be detected by microscopy. The fusion draw method offers the advantage that, because the two glass films flowing over the channel fuse together, neither of the outside surfaces of the resulting glass article comes in contact with any part of the apparatus. Thus, the surface properties of the fusion drawn glass article are not affected by such contact.

Some embodiments of the glass-based substrates described herein may be formed by a slot draw process. The slot draw process is distinct from the fusion draw method. In slot draw processes, the molten raw material glass is provided to a drawing tank. The bottom of the drawing tank has an open slot with a nozzle that extends the length of the slot. The molten glass flows through the slot and/or nozzle and is drawn downward as a continuous glass article and into an annealing region.

### Ion Exchange (IOX) Treatment

Chemical strengthening of glass substrates having base compositions is done by placing the ion-exchangeable glass substrates in a molten bath containing cations (K+, Na+, Ag+, etc) that diffuse into the glass while the smaller alkali ions (Na+, Li+) of the glass diffuse out into the molten bath. The replacement of the smaller cations by larger ones creates compressive stresses near the top surface of glass. Tensile stresses are generated in the interior of the glass to balance the compressive stresses.

With respect to ion exchange processes, they may independently be a thermal-diffusion process or an electro-diffusion process. Further additional strengthening treatments may be selected from the group consisting of: ion exchange, thermal annealing, thermal tempering, and combinations thereof.

After an ion exchange process is performed, it should be understood that a composition at the surface of a glass-based article may be different than the composition of the as-formed glass-based substrate (i.e., the glass-based object before it undergoes an ion exchange process). This results from one type of alkali metal ion in the as-formed glass-based substrate, for example, for example Li⁺ or Na⁺, being replaced with larger alkali metal ions, for example, for example Na⁺ or K⁺, respectively. However, the glass composition at or near the center of the depth of the glass-based article will, in embodiments, still have the composition of the as-formed glass-based substrate.

Some embodiments comprise a process for enriching a near-surface layer of the glass-based article with potassium ion (K) by exchanging in a salt that substantially does not alter the ratio between Na and Li of the interior of the glass-based article (e.g., at depths substantially deeper than the spike). The salt selected to obtain such enrichment via ion exchange is selected in such a way that the weight change of the article is preferably smaller than about 0.1(1+0.02/t) % after such ion exchange, which indicates that only potassium ions are being exchanged into the article (as significant weight gain would be expected if there were a substantial sodium (Na) enrichment in the average chemical composition of the article at the expense of lithium (Li); and significant weight loss would be expected if there were a substantial Li enrichment in the average chemical composition of the article at the expense of Na) where t is the thickness or the article or substrate in mm. The weight gain due to K enrichment may be considered negligible in most examples of the present disclosure due to the relatively shallow region of K enrichment in comparison to the glass thickness (DOLₛₚ generally less than 4-5% of thickness). An exemplary salt bath comprises mostly KNO₃ and less than or equal to 2 wt. % total of LiNO₃ and NaNO, where substantial change in the Na to Li ratio in the interior of the glass is avoided by not having a significant amount of LiNO₃ and NaNO₃ in the bath. In this case, a heat treatment step may be used after the K enrichment, to deepen the K distribution in the glass after the initial concentrated surface enrichment, such that after the heat treatment the K distribution achieves a depth in the range from 4 to 20 microns, preferably from 6 to 15 microns.

Some embodiments comprise a process for enriching a near-surface layer of the glass article with potassium ion (K) by exchanging in a salt that also enriches in Li relative to Na the interior of the glass article (e.g., at depths substantially deeper than the spike). In these embodiments, the Na/Li molar ratio in the interior of the article is decreasing relative to the substrate base composition. The salt selected to obtain such enrichment via ion exchange is selected in such a way that the article loses weight during the ion exchange, and the weight loss is from about 0.1% to about 3%; from about 0.1% to about 2%; from about 0.1% to about 1.5%; from about 0.1% to about 1%; from about 0.1% to about 0.7%; from about 0.1% to about 0.5%; or from about 0.1% to about 0.35%, depending on the initial glass composition and the number of steps of K and Li enrichment. In a multi-step enrichment process, the first step may preferably comprise ion exchange that has a substantially smaller weight change than subsequent steps, for example weight gain or loss of less than 0.1(1+0.02/t) % where t is the thickness in mm, or where weight loss from 0.1 to 0.35% is observed.

Some embodiments comprise the use of specific mixtures of salts comprising, for example, a mixture of K-enriching nitrates including KNO₃, LiNO₃, and NaNO₃, for achieving the K enrichment of the glass article with limited or no change in the Na to Li ratio in the interior of the glass (e.g., at depths larger than about 0.010·t). An example K-enriching composition for a lithium-based glass is 55 wt. % NaNO₃, 15 wt. % LiNO₃, and 30 wt. % KNO₃, which without being limiting, is advantageously used with a glass substrate whose base composition has a molar ratio of Na₂O to Li₂O of 1.69, or of greater than 1.3. Another example K-enriching composition for a lithium-based glass is 2 wt. % NaNO₃, 8 wt. % LiNO₃, and 90 wt. % KNO₃, which without being limiting, is advantageously used with a glass substrate whose base composition has a molar ratio of Na₂O to Li₂O of 0.63, or of less than 1.3, for example less than or equal to 1.3 and greater than or equal to 0.16, for example less than or equal to 1.2, or less than or equal to 1.1, or less than or equal to 1.0, or less than or equal to 0.9, or less than or equal to 0.8, or less than or equal to 0.7, or less than or equal to 0.6, or less than or equal to 0.5, or less than or equal to 0.4, or less than or equal to 0.3, including all values and subranges therebetween, including 0.63 and 0.29.

### End Products

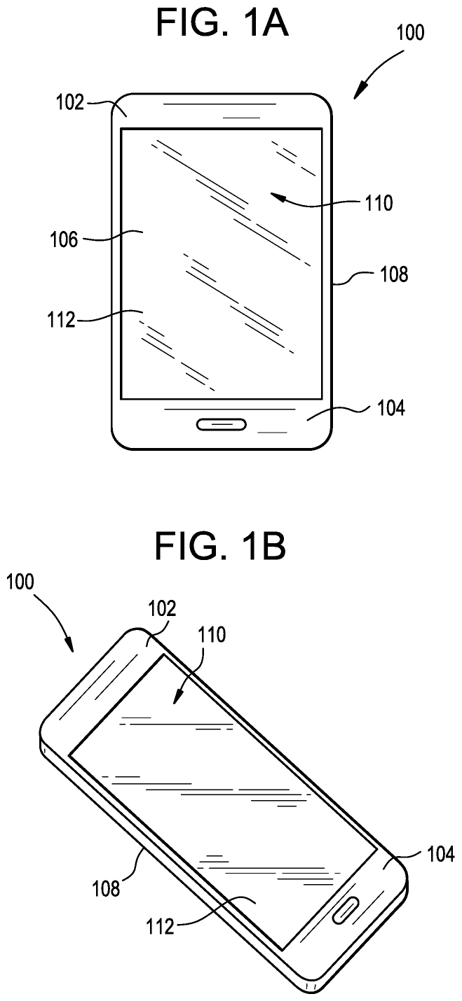

The glass-based articles disclosed herein may be incorporated into another article for example an article with a display (or display articles) (e.g., consumer electronics, including mobile phones, tablets, computers, watches, navigation systems, and the like), architectural articles, transportation articles (e.g., automobiles, trains, aircraft, sea craft, etc.), appliance articles, or any article that may benefit from some transparency, scratch-resistance, abrasion resistance or a combination thereof. FIGS. 1A and 1B. Specifically, FIGS. 1A and 1B show a consumer electronic device 100 including a housing 102 having front 104, back 106, and side surfaces 108; electrical components (not shown) that are at least partially inside or entirely within the housing and including at least a controller, a memory, and a display 110 at or adjacent to the front surface of the housing; and a cover plate 112 at or over the front surface of the housing such that it is over the display. In some embodiments, the at least a portion of cover plate 112 may include any of the glass-based articles disclosed herein. In some embodiments, at least a portion of the housing 102 may include any of the glass-based articles disclosed herein.

### EXAMPLES

Various embodiments will be further clarified by the following examples. In the Examples, prior to strengthening, the Examples are referred to as “substrates”. After being subjected to strengthening, the Examples are referred to as “articles” or “glass-based articles”.

Examples are based on one of the following compositions.

Composition A was a lithium-based glass-based substrate having the following base composition: 63.27 mol % SiO₂, 6.73 mol % B₂O₃, 15.17 mol % Al₂O₃, 4.32 mol % Na₂O, 6.86 mol % Li₂O, 1.02 mol % MgO, 0.02 mol % Fe₂O₃, 1.03 mol % SrO, 0.07 mol % SnO₂, and 1.55 mol % CaO. The base composition had a molar ratio of Na₂O to Li₂O of 0.63, which is less than 1.3, for example less than 1.2, or less than 1.1 or less than 1.0 or less than 0.9, or less than 0.8, or less than 0.7.

Composition B was a lithium-based glass-based substrate having the following base composition: 64.13 mol % SiO₂, 15.98 mol % Al₂O₃, 10.86 mol % Na₂O, 0.03 mol % K₂O, 6.42 mol % Li₂O, 0.08 mol % MgO, 1.17 mol % ZnO, 0.04 mol % SnO₂, 1.24 mol % P₂O₅, and 0.02 mol % CaO. The base composition had a molar ratio of Na₂O to Li₂O of 1.69, which is greater than 1.0, for example greater than or equal to 1.1, or greater than or equal to 1.2, or greater than or equal to 1.3.

Central tension (CT) was measured by scattering polarimetry using a SCALP-5 made by Glasstress Co., Estonia.

Compressive stress at the knee CSₖ was measured by a method according to U.S. Ser. No. 16/015,776, filed Jun. 22, 2018 to the assignee, which is incorporated herein by reference.

In the following “Reported FSM maximum compressive stress (CSₘₐₓ)” and “spike depth of layer (DOLₛₚ): were measured by a FSM-6000 LE from Orihara, Japan. FSM measurement allows for the maximum CS (CSₘₐₓ) occurring at the surface, and the CS decreases monotonically with depth, such that the maximum CS at the surface can be found from measurements of the mode spectra using prism coupling. The reported FSM maximum CS is then given by

$${CS}_{m ax} = \frac{{n}_{surf}^{TM} - {n}_{surf}^{TE}}{SOC} .$$

The surface indices n_{surf}^{TM} and n_{surf}^{TE} in the transverse magnetic (TM) and transverse electric (TE) polarization states are found from the positions of the first two fringes in the TM and TE mode spectra measured by prism coupling. The FSM software uses:

n_{surf}^{TM}(FSM)=n₁^{TM}+0.9×(n₁^{TM}−n₂^{TM}) and

n_{surf}^{TE}(FSM)=n₁^{TE}+0.9×(n₁^{TE}−n₂^{TE})

which represents a good approximation for a generic case when significant effects of stress relaxation and/or post-immersion diffusion may be present.

In the following, reference to surface stress (CS_{surface}) modifies the FSM software by using a different coefficient to allow for glasses for which ion exchange was performed at a temperature below 400° C. (negligible stress relaxation), and when post-ion-exchange cooling was fast (e.g., significant post-immersion diffusion was avoided), which can be accurately approximated as a linear distribution from the surface to the depth of the second mode (turning point of the second mode). In this case, the following modification is used in the CSₘₐₓ equation to calculate CS_{surface}, wherein “(lin)” stands for linear approximation:

n_{surf}^{TM}(lin)=n₁^{TM}+1.317×(n₁^{TM}−n₂^{TM})

n_{surf}^{TE}(lin)=n₁^{TE}+1.317×(n₁^{TE}−n₂^{TE}).

### Examples 1-4 and Example A (Comparative)

Glass-based articles were formed from 50 mm×50 mm×0.5 mm thick glass-based substrates of Composition A.

For Examples 1-4, a two-step ion exchange (IOX) treatment was conducted. The duration of step two was varied relative to step one. Samples were washed in deionized water (DI), wiped clean with acetone, and weighed with a high precision scale prior to starting the treatment.

The samples were preheated for 10 to 15 minutes to be close to the ion exchange temperature. The first step included a two-sided ion exchange in a first IOX bath having a composition of: 90 wt. % KNO₃, 8 wt. % LiNO₃, and 2 wt. % NaNO₃, and a temperature of: 420° C. Different samples were ion exchanged for 2, 4, 5.2, and 7.8 hours respectively in the first step bath and then individually characterized. Cleaning after first step ion exchange included washing the samples with deionized water to remove residual salt and then wiping clean with a cloth soaked in acetone.

The samples were then preheated in a stainless steel fixture with a combination of 10 minutes on a hot plate that was set at 300° C. covered by a 500 mL glass beaker to keep the heat in. This was followed by 3 minutes inside the ion exchange chamber set at 430° C. to ensure limited or no profile change. An initial second step included a two-sided ion exchange in a second IOX bath having a composition of: 85 wt. % KNO₃ and 15 wt. % NaNO₃, a temperature of: 430° C., and a duration of 2 hours. Cleaning after the initial second step ion exchange included washing the samples with deionized water to remove residual salt and then wiping clean with a cloth soaked in acetone.

Following the initial second step were multiple subsequent steps in the same bath of 85 wt. % KNO₃ and 15 wt. % NaNO₃ at 430° C. The pre-heat for each subsequent time point with the samples in a stainless steel fixture was a combination of 10 minutes on a hot plate that was set at 300° C. covered by a 500 mL glass beaker to keep the heat in. This was followed by 3 minutes inside the ion exchange chamber set at 430° C. to ensure little or no profile change. The samples were then placed inside the salt bath for a certain amount of time. The time points following the initial 2 hours were: 30 minutes, total of 2.5 hrs; plus 30 minutes, total of 3 hrs; plus 30 minutes, total of 3.5 hrs; plus 45 minutes, total of 4.25 hrs; plus 1 hr, total of 5.25 hrs. Before each ion exchange the samples had the same preheat described above of 10 minutes on the hot plate and 3 minutes inside the chamber. Cleaning after each second step ion exchange included washing the samples with deionized water to remove residual salt and then wiping clean with a cloth soaked in acetone.

For Example A, a comparative one-step ion exchange treatment was conducted using only the second IOX bath. That is, the duration of the first step was 0 hours (hr.).

Table 1 provides a summary of the conditions for each example and the resulting Reported FSM maximum compressive stress (CSₘₐₓ), surface stress (CS_{surface}), spike depth of layer (DOLₛₚ), and central tension (CT). Values of knee compressive stress (CSₖ) of Examples 1-4 after the 2nd step were in the range of: 118+20/−15 MPa.

TABLE 1

| | | | | Reported | | | |
|---|---|---|---|---|---|---|---|
| | | | | FSM | | | |
| | | Weight | | Maximum | | | |
| | | Gain | | Compressive | Surface | | |
| | 1st Step | after 1st | 2nd Step | Stress | Stress | | |
| | IOX Time | Step | IOX Time | (CSₘₐₓ) | (CS_{surface}) | DOLₛₚ | CT |
| Example | (hr.) | (%) | (hr.) | (MPa) | (MPa) | (μm) | (MPa) |
| A | 0 | — | 2 | — | 726 | 4.6 | 81.08 |
| | 0 | | 2.5 | — | 763 | 5.2 | 80.56 |
| | 0 | | 3 | 607 | 693 | 5.7 | 82.16 |
| | 0 | | 3.5 | 587 | 657 | 6.0 | 81.42 |
| | 0 | | 4.25 | 563 | 621 | 6.6 | 76.5 |
| | 0 | | 5.25 | 548 | 592 | 6.8 | 69.94 |
| 1 | 2 | −0.023 | 2 | 615 | 719 | 5.6 | 70.5 |
| | 2 | | 2.5 | 616 | 672 | 6.2 | 74.26 |
| | 2 | | 3 | 584 | 645 | 6.2 | 74.7 |
| | 2 | | 3.5 | 578 | 632 | 6.5 | 76.74 |
| | 2 | | 4.25 | 551 | 612 | 6.8 | 75.15 |
| | 2 | | 5.25 | 549 | 587 | 7.4 | 71.58 |
| 2 | 4 | −0.0027 | 2 | 605 | 666 | 6.4 | 65.28 |
| | 4 | | 2.5 | 598 | 648 | 6.4 | 73.94 |
| | 4 | | 3 | 581 | 636 | 6.4 | 74.54 |
| | 4 | | 3.5 | 571 | 620 | 6.7 | 75.2 |
| | 4 | | 4.25 | 562 | 610 | 7.2 | 74.58 |
| | 4 | | 5.25 | 562 | 593 | 7.7 | 72.78 |
| 3 | 5.2 | −0.038 | 2 | 597 | 657 | 6.4 | 60.64 |
| | 5.2 | | 2.5 | 583 | 638 | 6.7 | 67.74 |
| | 5.2 | | 3 | 582 | 628 | 6.7 | 70.7 |
| | 5.2 | | 3.5 | 568 | 617 | 7.0 | 70.9 |
| | 5.2 | | 4.25 | 561 | 605 | 7.4 | 72.14 |
| | 5.2 | | 5.25 | 543 | 588 | 7.9 | 70.14 |
| 4 | 7.8 | −0.011 | 2 | 595 | 641 | 7.0 | 56.76 |
| | 7.8 | | 2.5 | 588 | 630 | 7.3 | 63.3 |
| | 7.8 | | 3 | 575 | 624 | 7.3 | 67.66 |
| | 7.8 | | 3.5 | 576 | 614 | 7.7 | 67.6 |
| | 7.8 | | 4.25 | 564 | 606 | 7.8 | 73.8 |
| | 7.8 | | 5.25 | 559 | 591 | 8.8 | 69.8 |

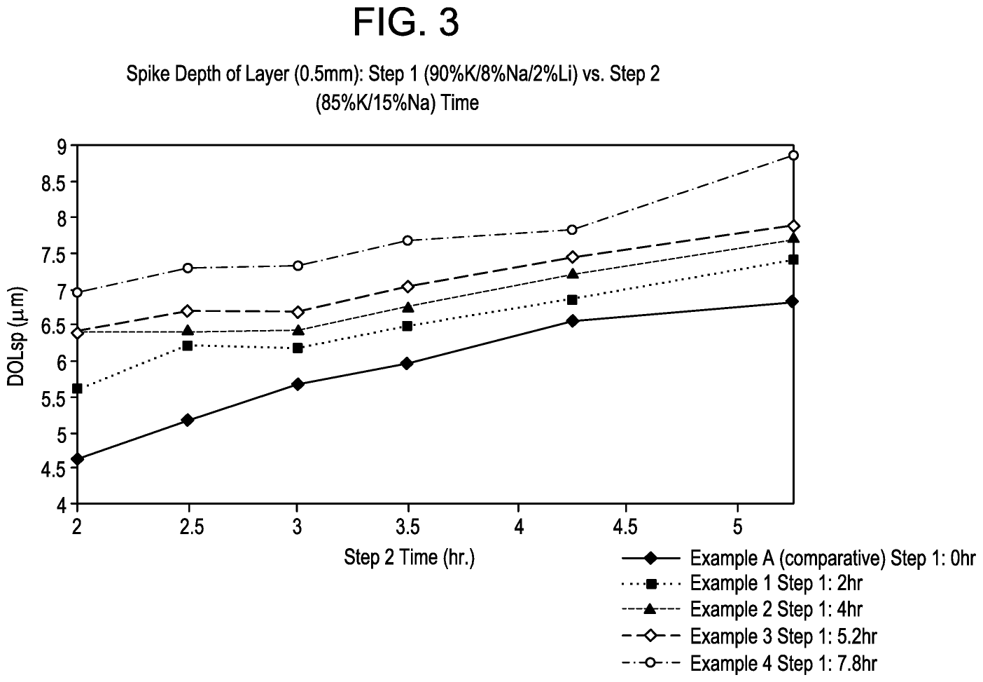

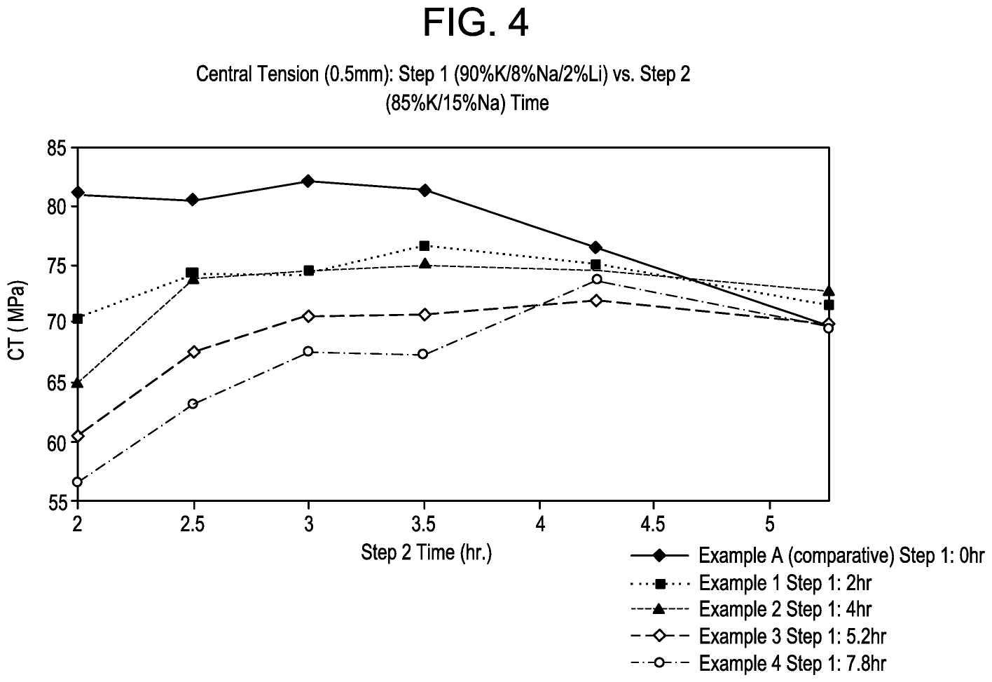

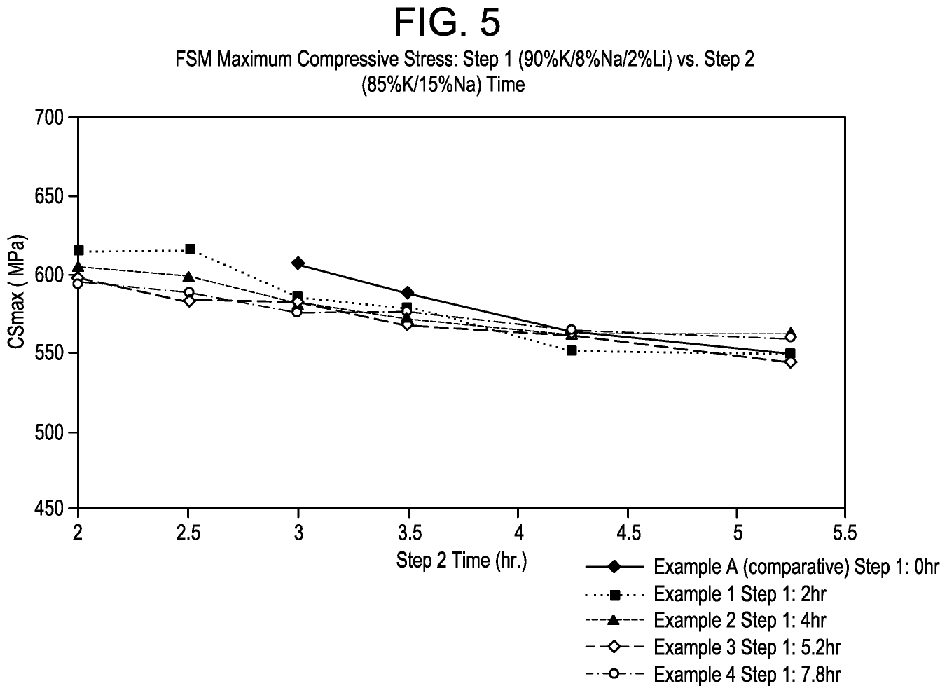

For Examples 1-4 and Example A (comparative) based on Table 1, FIG. 3 is a graph of spike depth of layer (DOLₛₚ) versus step 2 time (hrs.), FIG. 4 is a graph of central tension versus step 2 time (hrs.), and FIG. 5 is a graph of maximum compressive stress (CSₘₐₓ) versus step 2 time (hrs.).

With respect to DOLₛₚ, the data of Table 1 and FIG. 3 show that the longer the sample remained in the first step bath, the higher the DOLₛₚ value, resulting in a 2 to 2.3 μm increase. Also, a higher DOLₛₚ was achieved the longer the samples remained in the second step bath. The highest value of DOLₛₚ of 8.8 μm was achieved with: a 7.8 hour first step (Example 4) and a 5.25 hour second step.

Regarding CT, Table 1 and FIG. 4 show a loss of CT for Examples 1-4, which underwent a first step bath, up to 4.25 hours for the second step, in comparison to Example A (comparative), which did not have a first step ion exchange. This is a tradeoff for having a higher DOLₛₚ. At 5.25 hours, the CT values of Examples 1-4 were either higher or comparable relative to Example A (comparative).

As to CSₘₐₓ, at constant second step duration, Table 1 and FIG. 5 show comparable values for Examples 1-4 relative to Example A (comparative), noting that for Example A (comparative), the CSₘₐₓ was not included for 2 hours or for 2.5 hours due to limitations of the FSM 6000 to measure a sample having fewer than 2 fringes.

Examples 1-4 showed a weight loss after the first step ranging in absolute values from 0.0027% to 0.038%, which is shown in Table 1 as a negative percent in weight gain.

Table 1 and FIGS. 3-5 show that CSₘₐₓ at any given second step time remains about the same for each of the examples, but at the same the second step time CT decreases with increasing first step 1 time. Without intending to be bound by theory, the presence of the pre-spike (first step) increases the time that it takes in the subsequent Na-enrichment step (second step) to reach a maximum CT. This helps to achieve a higher DOLₛₚ, both because the pre-spike provides some K, and because K is given more time to get deeper in the subsequent step that also provides Na profile.

### Examples 5-8 and Example B (Comparative)

Glass-based articles were formed from 50 mm×50 mm×0.5 mm thick glass-based substrates of Composition A.

For Examples 5-8, a two-step ion exchange (IOX) treatment was conducted analogously to Examples 1-4, with the difference being in the first IOX bath composition and first step duration, and in the second step durations after the initial second step. The first step included a two-sided ion exchange in a first IOX bath having a composition of: 80 wt. % KNO₃, 16 wt. % LiNO₃, and 4 wt. % NaNO₃, and a temperature of: 420° C. Different samples were ion exchanged for 3, 6, 9, and 12 hours respectively in the first step.

As to the second step, the time points following the initial 2 hours were: 36 minutes, total of 2.6 hrs; plus 42 minutes, total of 3.3 hrs; plus 57 minutes, total of 4.25 hrs; plus 60 minutes, total of 5.25 hrs. The second step was carried out in a bath of 85 wt. % KNO₃, and 15 wt. % NaNO₃, at 430° C.

For Example B, a comparative one-step ion exchange treatment was conducted using only the second IOX bath. That is, the duration of the first step was 0 hours.

Table 2 provides a summary of the conditions for each example and the resulting Reported FSM maximum compressive stress (CSₘₐₓ), surface stress (CS_{surface}), spike depth of layer (DOLₛₚ), and central tension (CT). Values of knee compressive stress (CSₖ) of Examples 5-8 after the 2nd step were in the range of: 139+20/−15 MPa.

TABLE 2

| | | | | Reported | | | |
|---|---|---|---|---|---|---|---|
| | | | | FSM | | | |
| | | Weight | | Maximum | | | |
| | | Gain | | Compressive | Surface | | |
| | 1st Step | after 1st | 2nd Step | Stress | Stress | | |
| | IOX Time | Step | IOX Time | (CSₘₐₓ) | (CS_{surface}) | DOLₛₚ | CT |
| Example | (hr.) | (%) | (hr.) | (MPa) | (MPa) | (μm) | (MPa) |
| B | 0 | — | 2 | — | 763 | — | 84.7 |
| | 0 | | 2.6 | — | 814 | — | 83.2 |
| | 0 | | 3.3 | — | 659 | — | 83.8 |
| | 0 | | 4.25 | 572 | 614 | 6.6 | 78.4 |
| | 0 | | 5.25 | 556 | 601 | 7.1 | 74.1 |
| 5 | 3 | −0.053 | 2 | — | 844 | — | 78.8 |
| | 3 | | 2.6 | — | 663 | — | 78.9 |
| | 3 | | 3.3 | 596 | 654 | 6.5 | 82 |
| | 3 | | 4.25 | 585 | 623 | 6.9 | 78.1 |
| | 3 | | 5.25 | 558 | 610 | 7.2 | 78.7 |
| 6 | 6 | −0.081 | 2 | 626 | 700 | 5.9 | 77 |
| | 6 | | 2.6 | 598 | 666 | 6.3 | 75 |
| | 6 | | 3.3 | 595 | 641 | 6.8 | 78.7 |
| | 6 | | 4.25 | 584 | 620 | 7.2 | 79.3 |
| | 6 | | 5.25 | 559 | 607 | 7.5 | 78.9 |
| 7 | 9 | −0.094 | 2 | 609 | 678 | 6.3 | 71.5 |
| | 9 | | 2.6 | 598 | 661 | 6.6 | 74.6 |
| | 9 | | 3.3 | 596 | 646 | 6.8 | 77.9 |
| | 9 | | 4.25 | 589 | 625 | 7.6 | 78.1 |
| | 9 | | 5.25 | 564 | 611 | 7.8 | 76 |
| 8 | 12 | −0.11 | 2 | 629 | 670 | 6.7 | 70.4 |
| | 12 | | 2.6 | 609 | 654 | 7.0 | 71.3 |
| | 12 | | 3.3 | 590 | 640 | 7.6 | 74.5 |
| | 12 | | 4.25 | 573 | 623 | 7.6 | 76.4 |
| | 12 | | 5.25 | 566 | 606 | 7.6 | 77.4 |

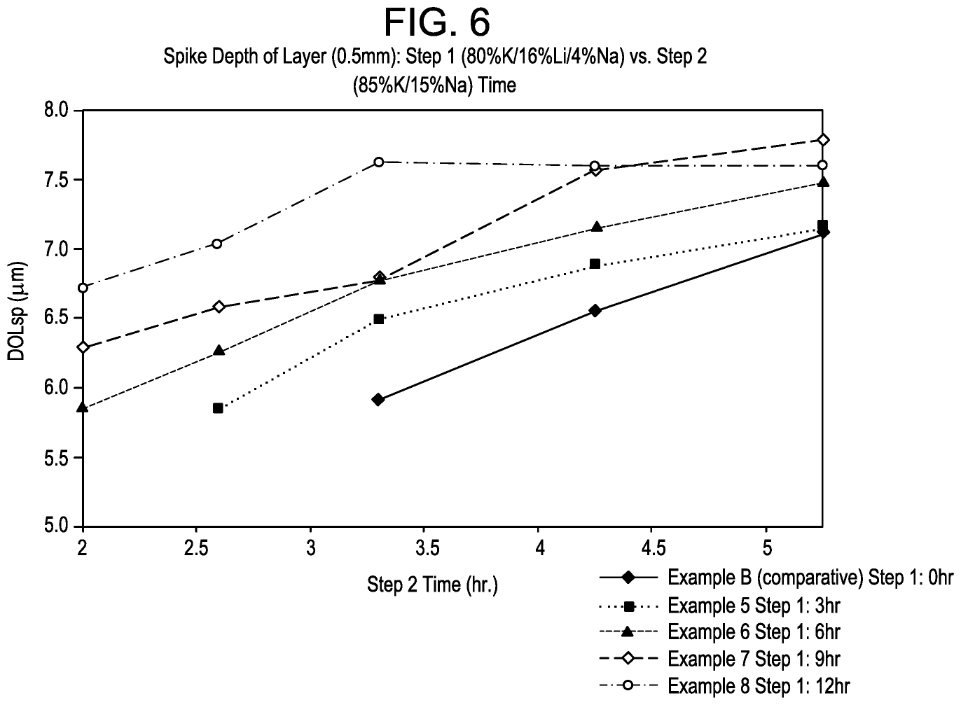

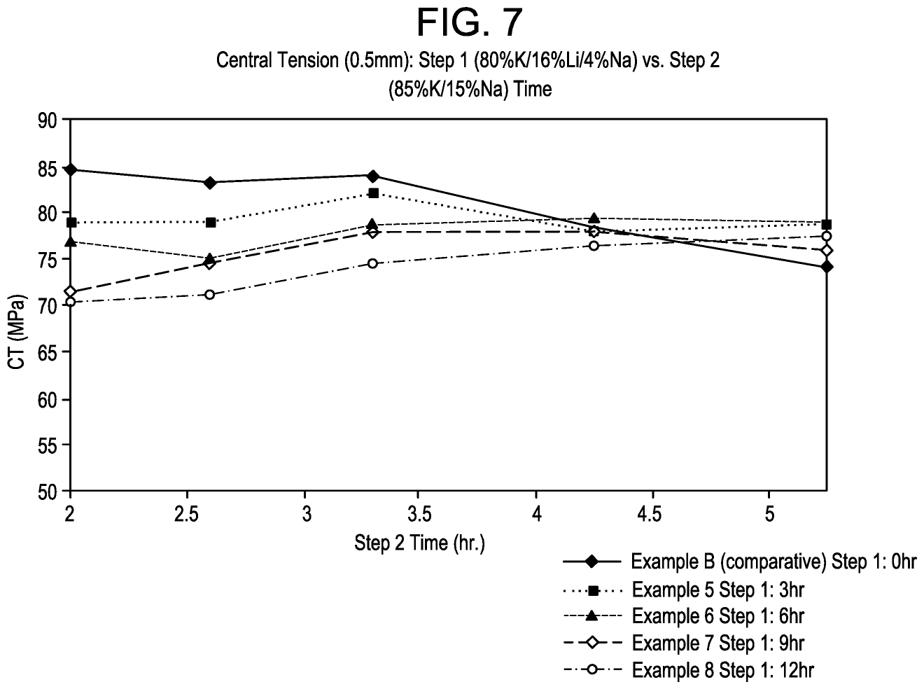

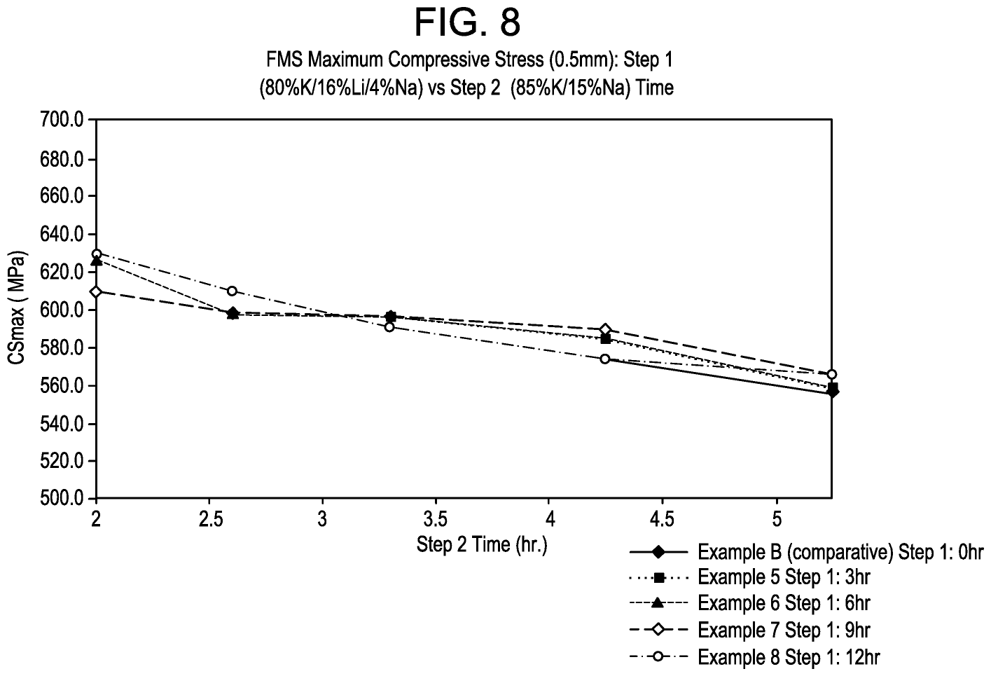

For Examples 5-8 and Example B (comparative) based on Table 2, FIG. 6 is a graph of spike depth of layer (DOLₛₚ) versus step 2 time (hrs.), FIG. 7 is a graph of central tension versus step 2 time (hrs.), and FIG. 8 is a graph of maximum compressive stress (CSₘₐₓ) versus step 2 time (hrs.).

With respect to DOLₛₚ, the data of Table 2 and FIG. 6 show that the longer the sample remained in the first step bath, the higher the DOLₛₚ value, resulting in a 0.6 to 1 μm increase. Also, a higher DOLₛₚ was achieved the longer the samples remained in the second step bath. The highest value of DOLₛₚ of 7.8 μm was achieved with: a 9 hour first step (Example 7) with a 5.25 hour second step.

Regarding CT, Table 2 and FIG. 7 show a loss of CT for Examples 5-8, which underwent a first step bath, up to 4.25 hours for the second step, in comparison to Example B (comparative), which did not have a first step ion exchange. This is a tradeoff for having a higher DOLₛₚ. At 5.25 hours, the CT values of Examples 5-8 were higher relative to Example B (comparative).

As to CSₘₐₓ, at constant second step duration, Table 2 and FIG. 8 show comparable values for Examples 5-8 relative to Example B (comparative), noting that for Example B (comparative), the CSₘₐₓ was not included for 2 hours or 2.6 hours due to limitations of the FSM 6000 to measure a sample having fewer than 2 fringes.

When DOLₛₚ is a priority, then preferred conditions are ones that have longer times for both the first step and the second step.

When DOLₛₚ and CT are both priorities at the same time, and production efficiency (short IOX time) is also of interest, then a shorter pre-spike step (first step) may be preferred, which also helps shorten the Na enrichment step(s) with a trade-off in a smaller DOLₛₚ.

Examples 5-8 showed a weight loss after the first step ranging in absolute values from 0.053% to 0.11%, which is shown in Table 2 as a negative percent in weight gain.

### Examples 9-12 and Example C (Comparative)

Glass-based articles were formed from 50 mm×50 mm×0.4 mm thick glass-based substrates of Composition A.

For Examples 9-12, a two-step ion exchange (IOX) treatment was conducted analogously to Examples 1-4, with the difference being in the first IOX bath composition and first step duration; and the initial second step duration and the second step durations after the initial second step. The first step was the same as that in Examples 5-8, which included a two-sided ion exchange in a first IOX bath having a composition of: 80 wt. % KNO₃, 16 wt. % LiNO₃, and 4 wt. % NaNO₃, and a temperature of: 420° C. Different samples were ion exchanged for 3, 6, 9, and 12 hours respectively in the first step.

As to the second step, the initial second step duration was 1 hour. The time points following the initial 1 hour were: 30 minutes, total of 1.5 hrs; plus 30 minutes, total of 2 hrs; plus 30 minutes, total of 2.5 hrs; plus 30 minutes, total of 3 hrs; plus 45 minutes, total of 3.75 hrs. The second step was carried out in a bath having a composition of: 85 wt. % KNO₃, 15 wt. % NaNO₃, and a temperature of: 430° C.

For Example C, a comparative one-step ion exchange treatment was conducted using only the second IOX bath. That is, the duration of the first step was 0 hours.

Table 3 provides a summary of the conditions for each example and the resulting Reported FSM maximum compressive stress (CSₘₐₓ), surface stress (CS_{surface}), spike depth of layer (DOLₛₚ), and central tension (CT). Values of knee compressive stress (CSₖ) of Examples 9-12 after the 2nd step were in the range of: 127+20/−15 MPa.

TABLE 3

| | | | | Reported | | | |
|---|---|---|---|---|---|---|---|
| | | | | FSM | | | |
| | | Weight | | Maximum | | | |
| | | Gain | | Compressive | Surface | | |
| | 1st Step | after 1st | 2nd Step | Stress | Stress | | |
| | IOX Time | Step | IOX Time | (CSₘₐₓ) | (CS_{surface}) | DOLₛₚ | CT |
| Example | (hr.) | (%) | (hr.) | (MPa) | (MPa) | (μm) | (MPa) |
| C | 0 | — | 1 | — | — | — | 81.5 |
| | 0 | | 1.5 | — | — | — | 89 |
| | 0 | | 2 | — | 747 | — | 83.6 |
| | 0 | | 2.5 | — | — | — | 83.3 |
| | 0 | | 3 | — | 781 | — | 79.9 |
| | 0 | | 3.75 | 563 | 638 | 6.1 | 71.8 |
| 9 | 3 | −0.064 | 1 | — | 783 | — | 67.6 |
| | 3 | | 1.5 | — | 807 | — | 79.2 |
| | 3 | | 2 | — | 871 | — | 79.5 |
| | 3 | | 2.5 | — | — | — | 79 |
| | 3 | | 3 | 577 | 656 | 6.0 | 79.2 |
| | 3 | | 3.75 | 553 | 618 | 6.5 | 76.5 |
| 10 | 6 | −0.091 | 1 | — | 863 | — | 62 |
| | 6 | | 1.5 | 567 | 747 | 5.5 | 75.6 |
| | 6 | | 2 | 606 | 701 | 5.9 | 78.5 |
| | 6 | | 2.5 | — | — | — | 76.8 |
| | 6 | | 3 | 567 | 641 | 6.3 | 78 |
| | 6 | | 3.75 | 575 | 620 | 7.0 | 76.7 |
| 11 | 9 | −0.12 | 1 | 617 | 726 | 5.7 | 62.3 |
| | 9 | | 1.5 | 653 | 700 | 6.1 | 72.9 |
| | 9 | | 2 | 604 | 670 | 6.2 | 74.9 |
| | 9 | | 2.5 | — | — | — | 76.9 |
| | 9 | | 3 | 581 | 632 | 6.7 | 79 |
| | 9 | | 3.75 | 566 | 616 | 7.0 | 76.8 |
| 12 | 12 | −0.13 | 1 | 622 | 692 | 6.1 | 57 |
| | 12 | | 1.5 | 640 | 675 | 6.5 | 71.4 |
| | 12 | | 2 | 609 | 657 | 6.7 | 72.5 |
| | 12 | | 2.5 | — | — | — | 77 |
| | 12 | | 3 | 587 | 633 | 7.0 | 77.8 |
| | 12 | | 3.75 | 565 | 616 | 7.3 | 73.9 |

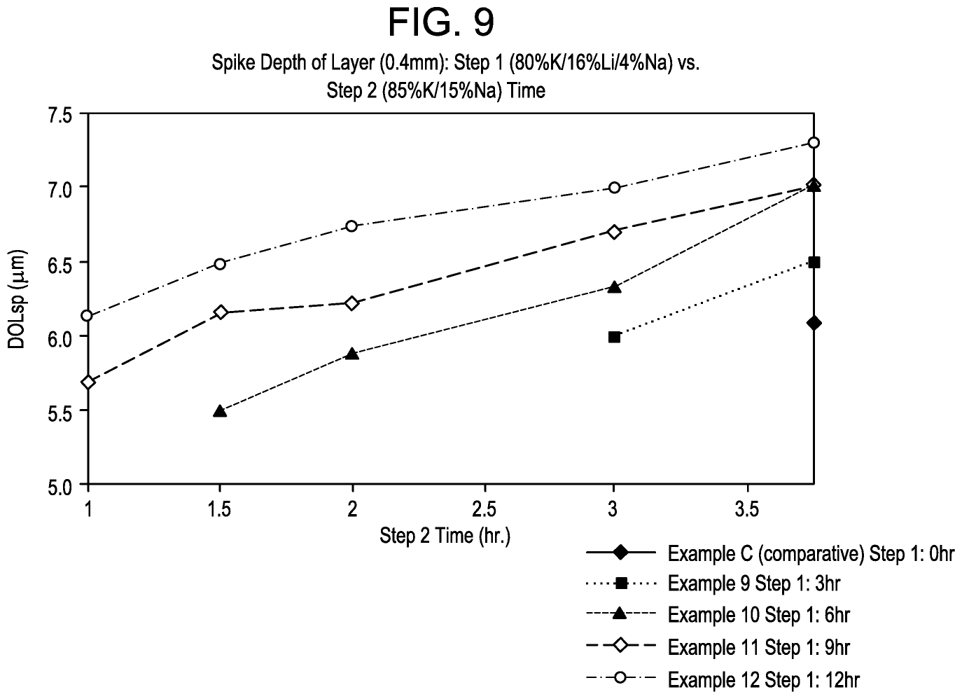

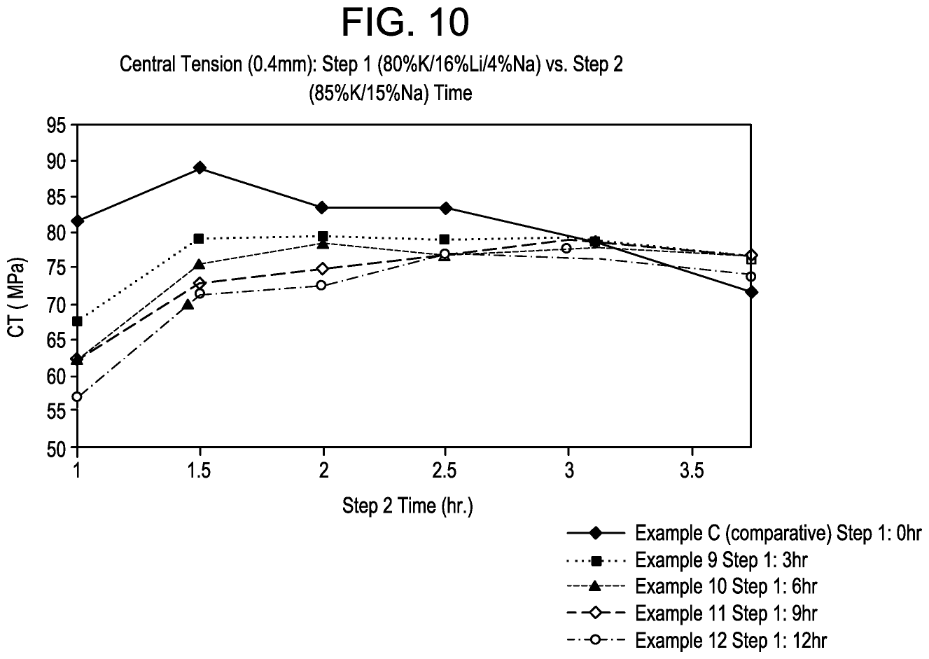

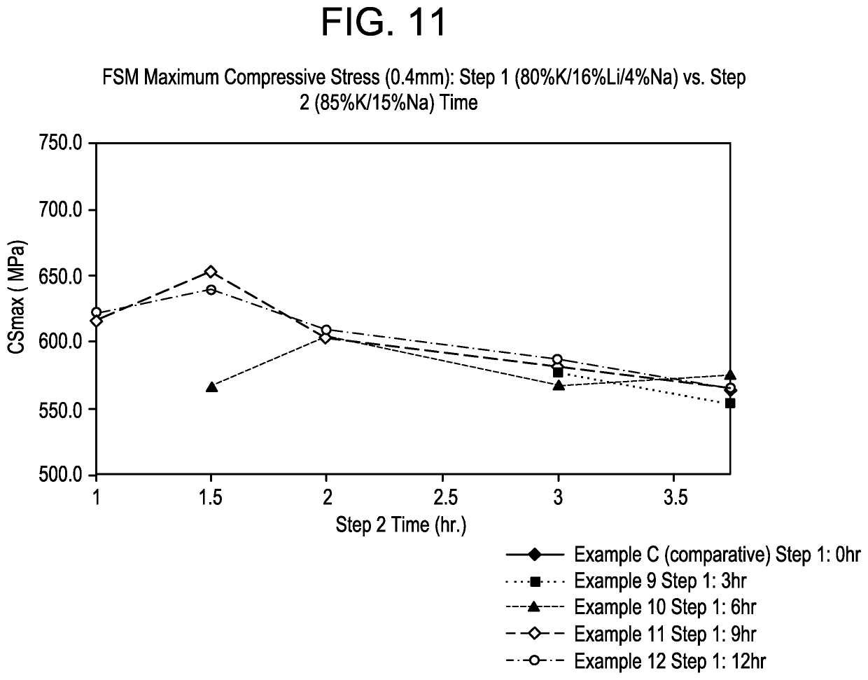

For Examples 9-12 and Example C (comparative) based on Table 3, FIG. 9 is a graph of spike depth of layer (DOLₛₚ) versus step 2 time (hrs.), FIG. 10 is a graph of central tension versus step 2 time (hrs.), and FIG. 11 is a graph of maximum compressive stress (CSₘₐₓ) versus step 2 time (hrs.).

With respect to DOLₛₚ, the data of Table 3 and FIG. 9 show that the longer the sample remained in the first step bath, the higher the DOLₛₚ value, resulting in a 1 to 1.3 μm increase. Also, a higher DOLₛₚ was achieved the longer the samples remained in the second step bath. The highest value of DOLₛₚ of 7.3 μm was achieved with: a 12 hour first step (Example 12) with a 3.75 hour second step.

Regarding CT, Table 3 and FIG. 10 show a loss of CT for Examples 9-12, which underwent a first step bath, up to 3 hours for the second step, in comparison to Example C (comparative), which did not have a first step ion exchange. This is a tradeoff for having a higher DOLₛₚ. At 3.75 hours, the CT values of Examples 9-12 were higher relative to Example C (comparative).

As to CSₘₐₓ, at constant second step duration, Table 3 and FIG. 11 show comparable values for Examples 9-12 relative to Example C (comparative), noting that for Example C (comparative), the CSₘₐₓ was not included for 1 hour, 1.5 hours, or for 2.5 hours due to limitations of the FSM 6000 to measure a sample having fewer than 2 fringes.

When DOLₛₚ is a priority, then preferred conditions are ones that have longer times for both the first step and the second step.

When DOLₛₚ and CT are both priorities at the same time, and production efficiency (short IOX time) is also of interest, then a shorter pre-spike step (first step) may be preferred, which also helps shorten the Na enrichment step(s) with a trade-off in a smaller DOLₛₚ.

Examples 9-12 showed a weight loss after the first step ranging in absolute values from 0.064% to 0.13%, which is shown in Table 3 as a negative percent in weight gain.

### Examples 13-16 and Example D (Comparative)

Glass-based articles were formed from 50 mm×50 mm×0.8 mm thick glass-based substrates of Composition A.

For Examples 13-16, a three-step ion exchange (IOX) treatment was conducted. The first step was conducted analogously to Examples 1-4, which included a bath composition of: 90 wt. % KNO₃, 8 wt. % LiNO₃, and 2 wt. % NaNO₃, and a temperature of: 420° C., with a difference being in the first step duration. The second step was conducted analogously to Examples 1-4, which included a bath composition of: 85 wt. % KNO₃ and 15 wt. % NaNO₃ and a temperature of: 430° C. A new third step was added, detailed in the following.

The first step included ion exchange durations of 1, 2, 3, and 4 hours respectively in the first step.

As to the second step, durations were: 6 hours and 6.75 hours.

The third step had a bath composition of: 96 wt. % KNO₃ and 4 wt. % NaNO₃ and a temperature of: 430° C. for a duration of 1 hour. The samples were preheated inside an oven for 3 minutes to ensure very little to no profile change. Cleaning after third step included washing the samples with deionized water to remove residual salt and then wiping clean with a cloth soaked in acetone.

For Example D, a comparative two-step ion exchange treatment was conducted using only the second and third IOX baths. That is, the duration of the first step was 0 hours.

Tables 4.A and 4.B provide a summary of the conditions for each example and the resulting Reported FSM maximum compressive stress (CSₘₐₓ), surface stress (CS_{surface}), spike depth of layer (DOLₛₚ), and central tension (CT), after the second step and after the third step, respectively. Values of knee compressive stress (CSₖ) of Examples 13-16 after the 2nd step were in the range of: 156+20/−15 MPa, and after the 3rd step were in the range of: 97+20/−15 MPa.

TABLE 4.A

| | | | | Reported | | | |
|---|---|---|---|---|---|---|---|
| | | | | FSM | | | |
| | | Weight | | Maximum | | | |
| | | Gain | | Compressive | Surface | | |
| | 1st Step | after 1st | 2nd Step | Stress | Stress | | |
| | IOX Time | Step | IOX Time | (CSₘₐₓ) | (CS_{surface}) | DOLₛₚ | CT |
| Example | (hr.) | (%) | (hr.) | (MPa) | (MPa) | (μm) | (MPa) |
| D | 0 | — | 6 | 587 | 634 | 7.1 | 80 |
| | 0 | | 6.75 | 573 | 624 | 7.7 | 82 |
| 13 | 1 | 0.047 | 6 | 587 | 633 | 7.3 | 77 |
| | 1 | | 6.75 | 581 | 628 | 7.9 | 81 |
| 14 | 2 | 0.0011 | 6 | 583 | 631 | 7.6 | — |
| | 2 | | 6.75 | 581 | 625 | 8.0 | 81 |
| 15 | 3 | 0.0067 | 6 | 587 | 632 | 7.9 | — |
| | 3 | | 6.75 | 584 | 625 | 8.5 | 79 |
| 16 | 4 | 0.00070 | 6 | 578 | 632 | 8.0 | — |
| | 4 | | 6.75 | 576 | 624 | 8.5 | 78 |

TABLE 4.B

| | | | Reported | | | |
|---|---|---|---|---|---|---|
| | | | FSM | | | |
| | | | Maximum | | | |
| | | | Compressive | Surface | | |
| | 1st Step | 3rd Step | Stress | Stress | | |
| | IOX Time | IOX Time | (CSₘₐₓ) | (CS_{surface}) | DOLₛₚ | CT |
| Example | (hr.) | (hr.) | (MPa) | (MPa) | (μm) | (MPa) |
| D | 0 | 1 | 693 | 762 | 8.4 | 78.82 |
| 13 | 1 | 1 | 691 | 752 | 8.1 | 76.24 |
| 14 | 2 | 1 | 685 | 752 | 8.8 | 75.52 |
| 15 | 3 | 1 | 689 | 759 | 8.8 | 75.08 |
| 16 | 4 | 1 | 689 | 757 | 9.0 | 74.68 |

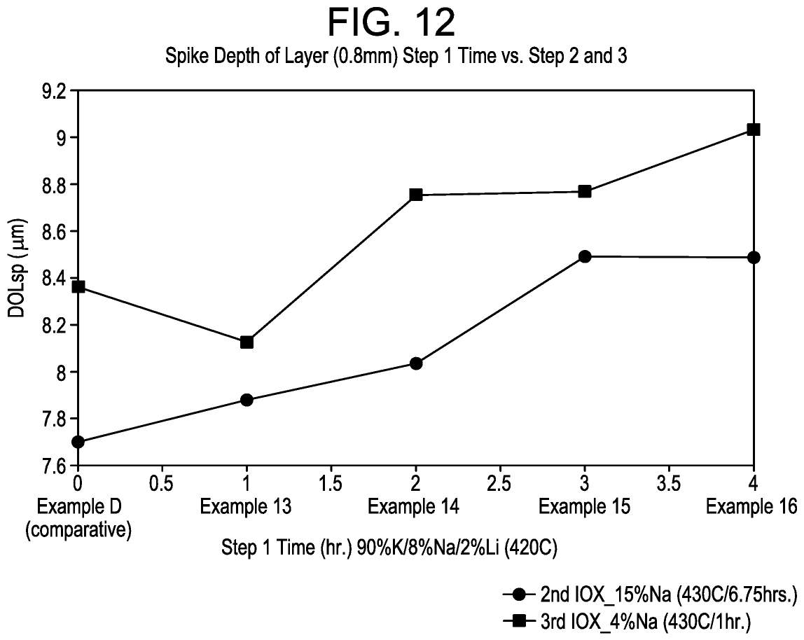

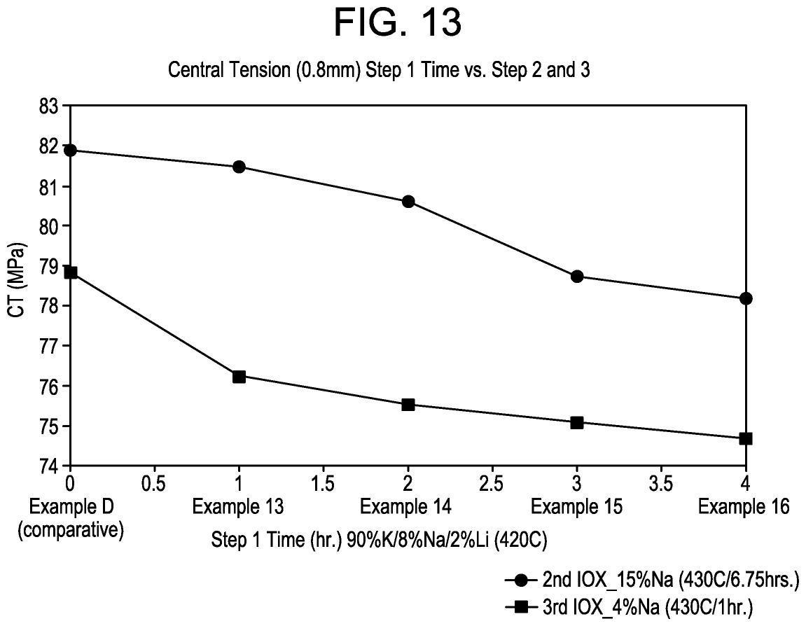

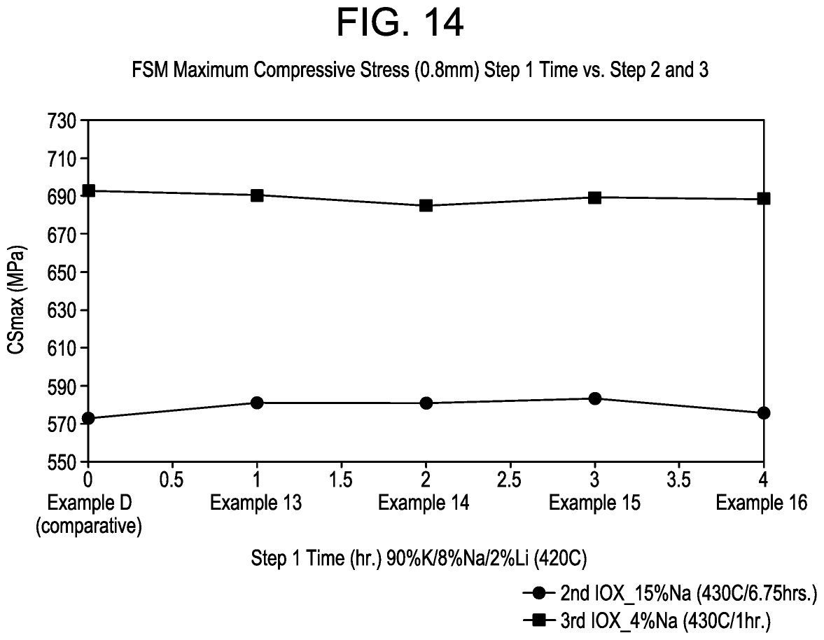

For Examples 13-16 and Example D (comparative) based on Tables 4.A and 4.B, FIG. 12 is a graph of spike depth of layer (DOLₛₚ) versus step 1 time (hrs.) for varying steps 2 and 3, FIG. 13 is a graph of central tension (CT) versus step 1 time (hrs.) for varying steps 2 and 3, and FIG. 14 is a graph of maximum compressive stress (CSₘₐₓ) versus step 2 time (hrs.).

With respect to DOLₛₚ, the data of Tables 4.A and 4.B and FIG. 12 show that the longer the sample remained in the first step bath, the higher the DOLₛₚ value, resulting in a 0.8 μm increase after the second step and a 0.7 μm increase after the third step. Also, a higher DOLₛₚ was achieved the longer the samples remained in the first and second step baths. Further, the data show that the third step also increases DOLₛₚ from that achieved in the second step. The increase relative to Example D (comparative) was modest.

Regarding CT, Tables 4.A and 4.B and FIG. 13 show that the longer the sample remained in the first step bath, the lower the CT was for both the second and third step ion exchanges. The compromise in CT was 3.7 MPa from 0 hr to 4 hrs in the first step bath, after the 2nd step ion exchange was complete. The compromise in CT was 4.1 MPa from 0 hr to 4 hrs in the first step bath after the third step ion exchange was complete.

As to CSₘₐₓ, at constant second step duration, Table 4.A and FIG. 14 show comparable values for Examples 13-16 relative to Example D (comparative) for all conditions of the first step. Additionally, CSₘₐₓ stays about the same after the second step no matter how long the first step. Similarly, CSₘₐₓ in the third step stays about the same, no matter how long the first step. Further, the data shows that the third step can be used to increase surface CS over that attained by the second step, but at the same time that third step reduces CT relative to that attained in the second step. In some cases the modest reduction in CSₖ and CT is a good trade-off for obtaining a significant boost in CSₘₐₓ, particularly if CSₘₐₓ is below 600 MPa without the boost.

Examples 13-16 showed a weight gain after the first step ranging in absolute values from 0.00070% to 0.047%.

### Examples 17-29 and Examples E-G (Comparative)

Glass-based articles were formed from 50 mm×50 mm×0.5 mm thick glass-based substrates of Composition B.

For Examples 17-29, a three-step ion exchange (IOX) treatment was conducted. The methods were analogous to those of Examples 13-16. The compositions with respect to nitrate salts (wt. %), temperatures, and durations of each are summarized in Tables 5.A and 5.B. For the first step, two different bath compositions were tested at 420° C. For the second step, two different bath compositions were tested at 380° C. for 1.42 hours. The third step was conducted with a bath of 87 wt. % KNO₃/13 wt. % NaNO₃ at 370° C. for 0.2 hours.

For Examples E-G, a comparative two-step ion exchange treatment was conducted using only the second and third IOX baths. That is, the duration of the first step was 0 hours.

Tables 5.A and 5.B also provide a summary of the conditions for each example and the resulting Reported FSM maximum compressive stress (CSₘₐₓ), surface stress (CS_{surface}), spike depth of layer (DOLₛₚ), and central tension (CT), after the second step and after the third step, respectively. Values of knee compressive stress (CSₖ) of Examples 17-22 after the 2nd step were in the range of: 166+20/−15 MPa. Values of knee compressive stress (CSₖ) of Examples 23-29 after the 2nd step were in the range of: 153+20/−15 MPa, and after the 3rd step were in the range of: 115-145+20/−15 MPa.

TABLE 5.A

| | | | | | Reported | | | |
|---|---|---|---|---|---|---|---|---|
| | | | | | FSM | | | |
| | | | Weight | 2nd Step IOX | Maximum | | | |
| | 1st Step IOX | | Gain | Composition | Compressive | Surface | | |
| | Composition | 1st Step | after 1st | wt. % | Stress | Stress | | |
| | wt. % | IOX Time | Step | at 380° C./ | (CSₘₐₓ) | (CS_{surface}) | DOLₛₚ | CT |
| Example | at 420° C. | (hr.) | (%) | 1.42 hrs | (MPa) | (MPa) | (μm) | (MPa) |
| E | — | 0 | — | 40%K/ | 489 | 501 | 7.8 | — |
| | | | | 60%Na | | | | |
| 17 | 20%K/64% | 0.55 | 0.0022 | 40%K/ | 440 | 482 | 8.5 | — |
| | Na/16%Li | | | 60%Na | | | | |
| 18 | 20%K/64% | 1 | 0.0033 | 40%K/ | 436 | 476 | 8.9 | — |
| | Na/16%Li | | | 60%Na | | | | |
| 19 | 20%K/64% | 1.55 | −0.0083 | 40%K/ | 440 | 485 | 9.3 | — |
| | Na/16%Li | | | 60%Na | | | | |
| F | N/A | 0 | — | 40%K/ | 457 | 509 | 7.5 | 65.4 |
| | | | | 60%Na | | | | |
| 20 | 30%K/55% | 0.5 | −0.018 | 40%K/ | 442 | 479 | 8.8 | 64.5 |
| | Na/15%Li | | | 60%Na | | | | |
| 21 | 30%K/55% | 0.8 | 0.0066 | 40%K/ | 436 | 469 | 10.5 | 67.3 |
| | Na/15%Li | | | 60%Na | | | | |
| 22 | 30%K/55% | 1.2 | 0.011 | 40%K/ | 432 | 472 | 11.8 | 67.2 |
| | Na/15%Li | | | 60%Na | | | | |
| G | N/A | 0 | — | 52%K/ | 497 | 539 | 8.0 | 66.9 |
| | | | | 48%Na | | | | |
| 23 | 20%K/64% | 0.55 | −0.00055 | 52%K/ | 498 | 538 | 8.2 | 66.1 |
| | Na/16%Li | | | 48%Na | | | | |
| 24 | 20%K/64% | 1 | −0.00055 | 52%K/ | 502 | 539 | 9.3 | — |
| | Na/16%Li | | | 48%Na | | | | |
| 25 | 20%K/64% | 1.5 | −0.0017 | 52%K/ | 480 | 541 | 10.0 | — |
| | Na/16%Li | | | 48%Na | | | | |
| 26 | 20%K/64% | 2.55 | −0.0061 | 52%K/ | 502 | 541 | 11.1 | — |
| | Na/16%Li | | | 48%Na | | | | |
| 27 | 30%K/55% | 0.5 | 0.032 | 52%K/ | 493 | 535 | 8.5 | 65.4 |
| | Na/15%Li | | | 48%Na | | | | |
| 28 | 30%K/55% | 0.8 | 0.0055 | 52%K/ | 491 | 533 | 9.9 | 64.8 |
| | Na/15%Li | | | 48%Na | | | | |
| 29 | 30%K/55% | 1.2 | 0.0088 | 52%K/ | 489 | 534 | 10.7 | 65.4 |
| | Na/15%Li | | | 48%Na | | | | |

TABLE 5.B

| | | | | Reported | | | |
|---|---|---|---|---|---|---|---|
| | | | 3rd Step IOX | FSM | | | |
| | | | Composition | Maximum | | | |
| | 1st Step IOX | | wt. % | Compressive | Surface | | |
| | Composition | 1st Step | 87%K/13% Na | Stress | Stress | | |
| | wt. % | IOX Time | at 370° C./ | (CSₘₐₓ) | (CS_{surface}) | DOLₛₚ | CT |
| Example | at 420° C. | (hr.) | time (hrs) | (MPa) | (MPa) | (μm) | (MPa) |
| E | — | 0 | 0.2 | 684 | 755 | 6.4 | 68.1 |
| 17 | 20%K/64%Na/ | 0.55 | 0.2 | 637 | 720 | 7.0 | 68.5 |
| | 16%Li | | | | | | |
| 18 | 20%K/64%Na/ | 1 | 0.2 | 646 | 695 | 8.4 | — |
| | 16%Li | | | | | | |
| 19 | 20%K/64%Na/ | 1.55 | 0.2 | 616 | 694 | 8.9 | — |
| | 16%Li | | | | | | |
| F | N/A | 0 | 0.2 | 688 | 780 | 6.4 | 71.4 |
| 20 | 30%K/55%Na/ | 0.5 | 0.2 | 659 | 702 | 7.3 | 69.8 |
| | 15%Li | | | | | | |
| 21 | 30%K/55%Na/ | 0.8 | 0.2 | 665 | 693 | 8.6 | — |
| | 15%Li | | | | | | |
| 22 | 30%K/55%Na/ | 1.2 | 0.2 | 638 | 692 | 9.9 | — |
| | 15%Li | | | | | | |
| G | N/A | 0 | 0.2 | 673 | 734 | 7.2 | 70.4 |
| 23 | 20%K/64%Na/ | 0.55 | 0.2 | 648 | 725 | 8.2 | — |
| | 16%Li | | | | | | |
| 24 | 20%K/64%Na/ | 1 | 0.2 | 661 | 720 | 9.2 | — |
| | 16%Li | | | | | | |
| 25 | 20%K/64%Na/ | 1.5 | 0.2 | 647 | 703 | 10.5 | — |
| | 16%Li | | | | | | |
| 26 | 20%K/64%Na/ | 2.55 | 0.2 | 648 | 713 | 11.2 | — |
| | 16%Li | | | | | | |
| 27 | 30%K/55%Na/ | 0.5 | 0.2 | 648 | 714 | 8.4 | — |
| | 15%Li | | | | | | |
| 28 | 30%K/55%Na/ | 0.8 | 0.2 | 653 | 719 | 9.7 | — |
| | 15%Li | | | | | | |
| 29 | 30%K/55%Na/ | 1.2 | 0.2 | 644 | 717 | 10.1 | — |
| | 15%Li | | | | | | |

FIG. 2 shows a modeled stress profile for Example 29, wherein for a thickness of 500 micrometers, a maximum compressive stress (CSₘₐₓ) was about 717 MPa, the compressive stress at the knee (CSₖ) was in the range of from about 110 to about 120 MPa, the spike depth of layer (DOLₛₚ) was about 10.7 micrometers (0.0214·t), the depth of compression (DOC) was in the range of from about 89 to about 94 micrometers (0.194), and the central tension (CT) was in the range of from about 64 to about 70 MPa.

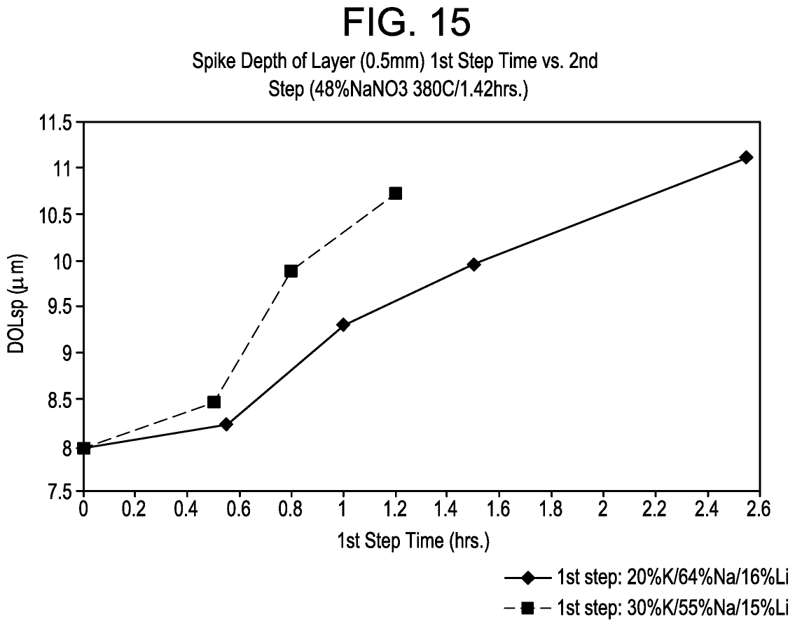

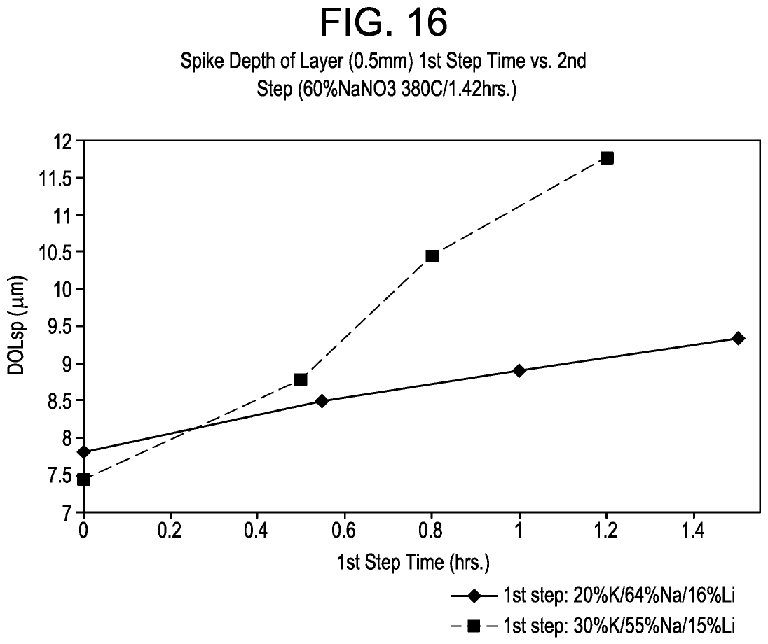

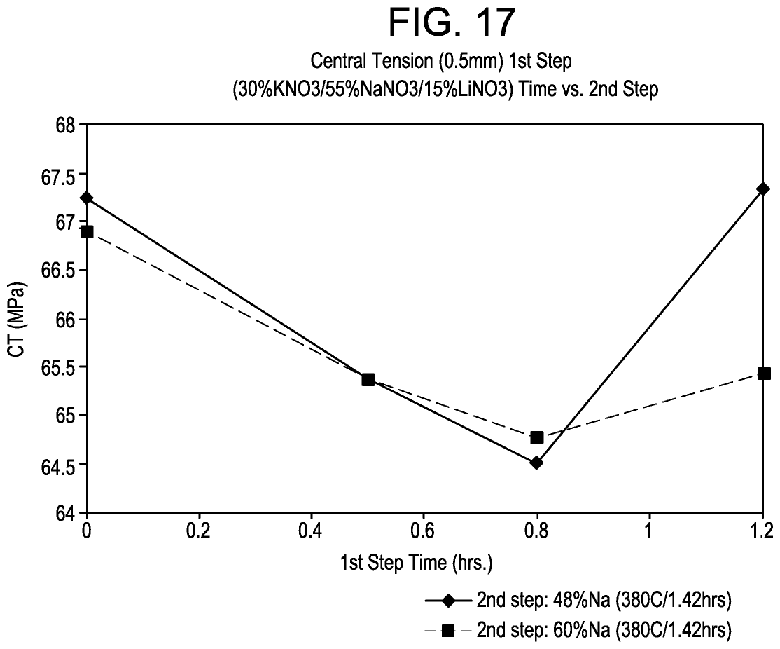

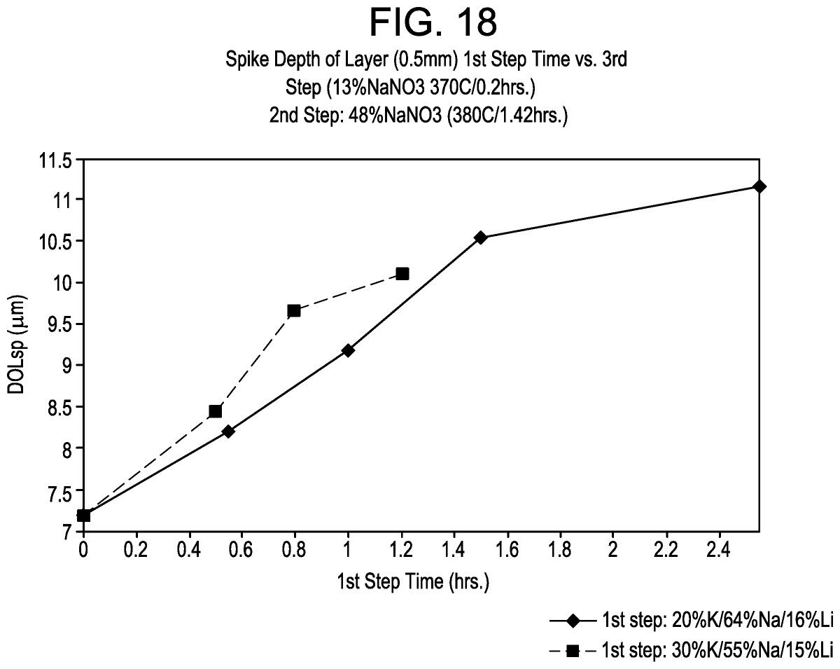

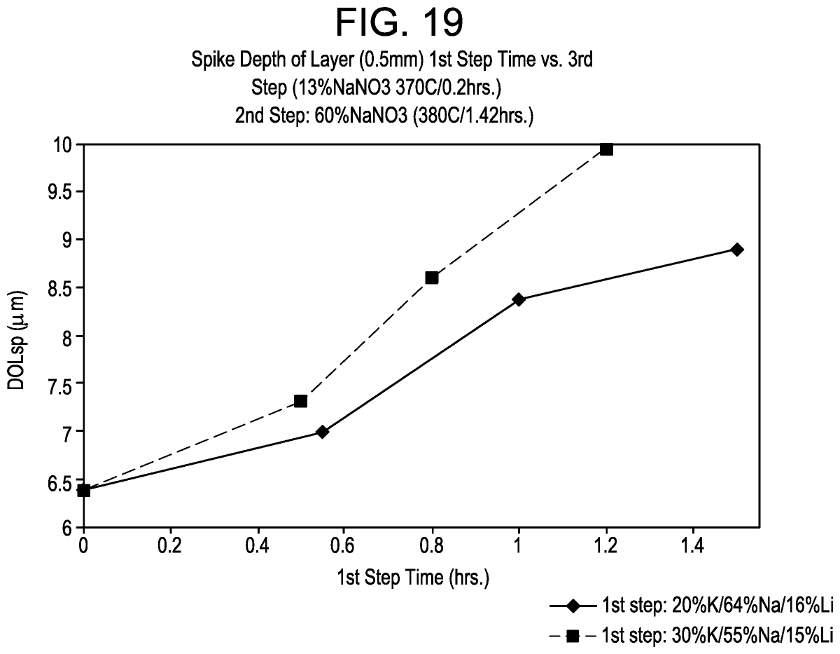

Based on Tables 5.A and 5.B, FIGS. 15-16 are graphs of spike depth of layer (DOLₛₚ) for first step 1 time (hrs.) versus second step bath type; FIG. 17 is a graph of central tension (CT) for a first step bath versus varied second step; FIGS. 18-19 are graphs of spike depth of layer (DOLₛₚ) for first step 1 time (hrs.) versus third step for differing first step bath types.

With respect to DOLₛₚ, the data shows that for a 52% K/48% Na second step, the samples treated with a first bath composition of 30% KNO₃, 15% LiNO₃, 55% NaNO₃ bath for same IOX times (Examples 27-29) had a higher DOLₛₚ in comparison to the samples treated with a first bath composition of 20% KNO₃, 16% LiNO₃, 64% NaNO₃ (Examples 23-25). The same is true for these samples after the third step.

The data shows that for a 60% K/40% Na second step, the samples treated with a first bath composition of 30% KNO₃, 15% LiNO₃, 55% NaNO₃ bath for comparable IOX times (Examples 20-22) had a slightly higher DOLₛₚ in comparison to the samples treated with a first bath composition of 20% KNO₃, 16% LiNO₃, 64% NaNO₃ (Examples 17-19). Occasionally the this trend may appear broken, due to DOLₛₚ measurement errors occurring as a result of inaccuracies in the estimate of the fringe count by the FSM software. Such errors are less than 0.2 microns when the non-integer fraction of the fringe count is between 0.15 and 0.7, but can be as high as 1 micron when the fractional part of the fringe count is outside of this interval from 0.15 to 0.70. After the third step, the DOLₛₚ were comparable for Examples 20-22 and Examples 17-19 for comparable IOX times.

Regarding CT, the data shows comparable CT was for both second bath conditions.

As to CSₘₐₓ, at constant second step duration, Table 5.A shows that the bath having 60% NaNO₃ by weight produces compressive stress in the range 469 MPa to about 510 MPa for the presented examples, as measured with the FSM-6000 software, while the bath having 48% NaNO₃ produces higher CS values up to 540 MPa; and Table 5.B shows that a third bath having 13% NaNO₃ and 87% KNO₃ produces maximum CS values in the range 692 MPa to 755 MPa.

Examples 17-29 showed various small weight gains and losses after the first step, in line with the intent that the interior of the glass substrate be either substantially unchanged, or slightly enriched in Li, but not substantially enriched in Na during the first step. Substantial weight gain such as above 0.07%, and especially above 0.10% or 0.15%, would indicate non-negligible enrichment in Na, given the relatively small amount of K being introduced in the glass. The weight gains in the given examples are substantially smaller than these values, indicating excellent choice of the bath composition to be in partial equilibrium for K-only enrichment near the surface.

### Example 30

A prophetic example of a glass-based article that is formed from 50 mm×50 mm×0.5 mm thick glass-based substrate of Composition B follows. For the first step, IOX bath composition is either of the two different bath compositions of Examples 17-29 at 420° C. The second and third steps of Examples 17-29 are combined, specifically the second step (40% KNO₃/60% NaNO₃, 1.42 hours) and third step (87% KNO₃/13% NaNO₃, 0.2 hours) are replaced with a single long step (87% KNO₃/13% NaNO₃, 1.4-1.6 hours). The resulting glass-based article has: CSₘₐₓ of greater than or equal to 710 MPa, DOLₛₚ of from about 8.2 to about 12 microns depending on the first-step duration (0.5 to 1.2 hours), with the main difference that CSₖ would be lower (70-100 MPa), and CT would also be lower (50-60 MPa).

### Example 31

A prophetic example of a glass-based article that is formed in accordance with the same substrate and the first two steps of Examples 17-29 along with a modified third step. The third step is a 12-25 minute IOX at 380C in a bath of 100% KNO₃. CSₘₐₓ is in the range 1100-1200 MPa, and high DOLₛₚ of from about 8 to about 9 microns.

While the foregoing is directed to various embodiments, other and further embodiments of the disclosure may be devised without departing from the basic scope thereof, and the scope thereof is determined by the claims that follow. The features of the present disclosure may be combined in any and all combinations, for example as set forth in the following embodiments.

Embodiment 1. A glass-based article comprising:
a lithium-based aluminosilicate composition;
a glass-based substrate having opposing first and second surfaces defining a substrate thickness (t), wherein t is less than or equal to 0.74 mm; and
a stress profile comprising:
a spike region extending from the first surface and comprising a spike depth of layer (DOLₛₚ) located at a depth of greater than or equal to 7 micrometers; and
a maximum central tension (CTₘₐₓ) of greater than or equal to 50 MPa.

Embodiment 2. A glass-based article comprising:
a lithium-based aluminosilicate composition;
a glass-based substrate having opposing first and second surfaces defining a substrate thickness (t), wherein t is less than or equal to 0.74 mm; and
a stress profile comprising:
a spike region extending from the first surface and comprising a spike depth of layer (DOLₛₚ) located at a depth of greater than or equal 0.010·t; and
a maximum central tension (CTₘₐₓ) of greater than or equal to 50 MPa.

Embodiment 3. The glass-based article of any preceding Embodiment, wherein t is greater than or equal to 0.05 millimeters.

Embodiment 4. The glass-based article of any preceding Embodiment, wherein a molar ratio of Na₂O to Li₂O in the lithium-based aluminosilicate composition is less than or equal to 1.3.

Embodiment 5. A glass-based article comprising:
a lithium-based aluminosilicate composition, wherein a molar ratio of Na₂O to Li₂O in the lithium-based aluminosilicate composition is less than or equal to 1.3;
a glass-based substrate having opposing first and second surfaces defining a substrate thickness (t); and
a stress profile comprising:
a spike region extending from the first surface and comprising a spike depth of layer (DOLₛₚ) located at a depth of greater than or equal to 7 micrometers; and
a maximum central tension (CTₘₐₓ) of greater than or equal to 50 MPa.

Embodiment 6. A glass-based article comprising:
a lithium-based aluminosilicate composition, wherein a molar ratio of Na₂O to Li₂O in the lithium-based aluminosilicate composition is less than or equal to 1.3;
a glass-based substrate having opposing first and second surfaces defining a substrate thickness (t); and
a stress profile comprising:
a spike region extending from the first surface and comprising a spike depth of layer (DOLₛₚ) located at a depth of greater than or equal 0.010·t; and
a maximum central tension (CTₘₐₓ) of greater than or equal to 50 MPa.

Embodiment 7. The glass-based article of any of Embodiment 6 to the preceding Embodiment, wherein t is greater than or equal to 0.05 millimeters and less than or equal to 1 millimeter.

Embodiment 8. The glass-based article of the preceding Embodiment, wherein t is greater than or equal to 0.35 millimeters and less than or equal to 0.8 millimeter.

Embodiment 9. The glass-based article of any preceding Embodiment, wherein a molar ratio of Na₂O to Li₂O in the lithium-based aluminosilicate composition is greater than or equal to 0.1.

Embodiment 10. The glass-based article of any preceding Embodiment, wherein a K₂O content the lithium-based aluminosilicate composition is less than or equal to 1.4 mol %.

Embodiment 11. The glass-based article of the preceding Embodiment, wherein a K₂O content the lithium-based aluminosilicate composition is less than or equal to 0.4 mol %.

Embodiment 12. The glass-based article of any preceding Embodiment, wherein the DOLₛₚ is less than or equal to 20 micrometers.

Embodiment 13. The glass-based article of any preceding Embodiment, wherein the DOLₛₚ is greater than or equal to 0.015·t.

Embodiment 14. The glass-based article of the preceding Embodiment, wherein the DOLₛₚ is greater than or equal to 0.020·t.

Embodiment 15. The glass-based article of any preceding Embodiment, wherein the stress profile further comprises a depth of compression (DOC) that is greater than or equal to 0.16·t.

Embodiment 16. The glass-based article of any preceding Embodiment, wherein the stress profile further comprises a maximum compressive stress (CSₘₐₓ) of greater than or equal to 400 MPa.

Embodiment 17. The glass-based article of any preceding Embodiment, wherein the stress profile further comprises a knee compressive stress (CSₖ) of greater than or equal to 85 MPa.

Embodiment 18. The glass-based article of any preceding Embodiment, wherein the central tension (CT) is greater than or equal to 55 MPa.

Embodiment 19. The glass-based article of the preceding Embodiment, wherein the central tension (CT) is greater than or equal to 60 MPa.

Embodiment 20. The glass-based article of the preceding Embodiment, wherein the central tension (CT) is greater than or equal to 65 MPa.

Embodiment 21. The glass-based article of the preceding Embodiment, wherein the central tension (CT) is greater than or equal to 70 MPa.

Embodiment 22. The glass-based article of any preceding Embodiment comprising potassium oxide (K₂O) having a non-zero concentration that varies from the first surface to a potassium depth of layer (DOL_{K}).

Embodiment 23. The glass-based article of the preceding Embodiment, wherein the stress profile further comprises a depth of layer of potassium (DOL_{K}) that is approximately equal to DOLₛₚ.

Embodiment 24. The glass-based article of any preceding Embodiment, wherein the stress profile further comprises:
a tail region extending from the spike region to a center of the glass-based article; and
wherein all points of the stress profile located in the spike region comprise a tangent having a slope with an absolute value that is 20 MPa/micrometer or greater, and all points of the stress profile located in the tail region comprise a tangent having a slope with an absolute value that is less than 20 MPa/micrometer.

Embodiment 25. A glass-based article comprising:
a lithium-based aluminosilicate composition;
a glass-based substrate having opposing first and second surfaces defining a substrate thickness (t), wherein t is greater than or equal to 0.05 millimeters and less than or equal to 0.74 millimeter;
potassium oxide (K₂O) having a non-zero concentration that varies from the first surface to a potassium depth of layer (DOL_{K}); and
a stress profile comprising:
a maximum compressive stress (CSₘₐₓ) of greater than or equal to 400 MPa;
a spike region extending from the first surface to a tail region and comprising a spike depth of layer (DOLₛₚ) located at a depth of greater than or equal 0.010·t; and a knee compressive stress (CSₖ) of greater than or equal to 85 MPa; and
the tail region extending from the spike region to a center of the glass-based article and comprising a maximum central tension (CTₘₐₓ) of greater than or equal to 50 MPa.

Embodiment 26. A glass-based article comprising:
a lithium-based aluminosilicate composition, wherein a molar ratio of Na₂O to Li₂O in the lithium-based aluminosilicate composition is less than or equal to 1.3;
a glass-based substrate having opposing first and second surfaces defining a substrate thickness (t);
potassium oxide (K₂O) having a non-zero concentration that varies from the first surface to a potassium depth of layer (DOL_{K}); and
a stress profile comprising:
a maximum compressive stress (CSₘₐₓ) of greater than or equal to 400 MPa;
a spike region extending from the first surface to a tail region and comprising a spike depth of layer (DOLₛₚ) located at a depth of greater than or equal 0.010·t; and a knee compressive stress (CSₖ) of greater than or equal to 85 MPa; and
the tail region extending from the spike region to a center of the glass-based article and comprising a maximum central tension (CTₘₐₓ) of greater than or equal to 50 MPa.

Embodiment 27. The glass-based article of one of Embodiment 23 to the preceding Embodiment, wherein the stress profile further comprises a depth of layer of potassium (DOL_{K}) that is approximately equal to DOLₛₚ.

Embodiment 28. A consumer electronic product comprising:
a housing having a front surface, a back surface, and side surfaces;
electrical components at least partially within the housing, the electrical components comprising at least a controller, a memory, and a display, the display at or adjacent the front surface of the housing; and
a cover disposed over the display;
wherein at least a portion of at least one of the housing and the cover comprises the glass-based article of one of Embodiments 1 to 27.

Embodiment 29. A method of manufacturing a glass-based article comprising:
exposing a glass-based substrate that comprises sodium oxide and lithium oxide in a base composition, the glass-based substrate having opposing first and second surfaces defining a substrate thickness (t), to an ion exchange treatment to form the glass-based article, the ion exchange treatment comprising:
a first bath comprising a potassium salt and a sodium salt and a lithium salt; and
a second bath comprising a potassium salt, a sodium salt, and optionally a lithium salt;
wherein the one of the following is met:
t is less than or equal to 0.74 mm;
the substrate comprises a composition wherein a molar ratio of Na₂O to Li₂O in the lithium-based aluminosilicate composition is less than or equal to 1.3; or
t is less than or equal to 0.74 mm and the substrate comprises a composition wherein a molar ratio of Na₂O to Li₂O in the lithium-based aluminosilicate composition is less than or equal to 1.3;
wherein the glass-based article comprises a stress profile comprising:
a spike region extending from the first surface and comprising a spike depth of layer (DOLₛₚ) located at a depth of greater than or equal to 0.010·t; and
a maximum central tension (CTₘₐₓ) of greater than or equal to 50 MPa.

Embodiment 30. The method of Embodiment 29, wherein after exposure to the first bath, an absolute value of weight gain of the glass-based substrate is less than or equal to 0.1(1+0.02/0%.

Embodiment 31. The method of one of Embodiment 29 to the preceding Embodiment, wherein content of the sodium salt in the second bath is greater that content of the sodium salt in the first bath.

Embodiment 32. The method of one of Embodiments 29 to 31, wherein the ion exchange treatment further comprises a third bath comprising a potassium salt and a sodium salt wherein content of the potassium salt in the third bath is greater than or equal to 90% by weight.

Embodiment 33. The method of one of Embodiments 29 to 31, wherein the first bath comprises: 50-60 wt. % NaNO₃, 10-20 wt. % LiNO₃, and 25-35 wt. % KNO₃, wherein content of the NaNO₃, LiNO₃, and KNO₃ totals 100%, and the glass substrate comprises a base composition having a molar ratio of Na₂O to Li₂O of greater than or equal to 1.3.

Embodiment 34. The method of one of Embodiments 29 to 31, wherein the first bath comprises: 1-3 wt. % NaNO₃, 6-10 wt. % LiNO₃, and 88-90 wt. % KNO₃, wherein content of the NaNO₃, LiNO₃, and KNO₃ totals 100%, and the glass substrate comprises a base composition having a molar ratio of Na₂O to Li₂O of less than or equal to 1.3.

Directional terms as used herein—for example up, down, right, left, front, back, top, bottom, inward, outward—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

As used herein, the terms “comprising” and “including,” and variations thereof, shall be construed as synonymous and open ended, unless otherwise indicated. A list of elements following the transitional phrases comprising or including is a non-exclusive list, such that elements in addition to those specifically recited in the list may also be present.

1.-34. (canceled)

35. A glass-based article comprising:
a lithium-based aluminosilicate composition;
a glass-based substrate having opposing first and second surfaces defining a substrate thickness (t), wherein t is less than or equal to 0.74 mm; and
a stress profile comprising:
a spike region extending from the first surface and comprising a spike depth of layer (DOLₛₚ) located at a depth of greater than or equal 0.010·t; and
a maximum central tension (CTₘₐₓ) of greater than or equal to 50 MPa.

36. The glass-based article of claim 35, wherein t is greater than or equal to 0.05 millimeters.

37. The glass-based article of claim 35, wherein a molar ratio of Na₂O to Li₂O in the lithium-based aluminosilicate composition is less than or equal to 1.3.

38. A glass-based article comprising:
a lithium-based aluminosilicate composition, wherein a molar ratio of Na₂O to Li₂O in the lithium-based aluminosilicate composition is less than or equal to 1.3;
a glass-based substrate having opposing first and second surfaces defining a substrate thickness (t); and
a stress profile comprising:
a spike region extending from the first surface and comprising a spike depth of layer (DOLₛₚ) located at a depth of greater than or equal 0.010·t; and
a maximum central tension (CTₘₐₓ) of greater than or equal to 50 MPa.

39. The glass-based article of claim 38, wherein t is greater than or equal to 0.05 millimeters and less than or equal to 1 millimeter.

40. The glass-based article of claim 35, wherein the stress profile further comprises a depth of compression (DOC) that is greater than or equal to 0.16·t.

41. The glass-based article of claim 35, wherein the stress profile further comprises a maximum compressive stress (CSₘₐₓ) of greater than or equal to 400 MPa.

42. The glass-based article of claim 35, wherein the stress profile further comprises a knee compressive stress (CSₖ) of greater than or equal to 70 MPa.

43. The glass-based article of claim 35, wherein the central tension (CT) is greater than or equal to 55 MPa.

44. The glass-based article of claim 35, wherein the stress profile further comprises a depth of layer of potassium (DOL_{K}) that is approximately equal to DOLₛₚ.

45. The glass-based article of claim 35, wherein the stress profile further comprises:
a tail region extending from the spike region to a center of the glass-based article; and
wherein all points of the stress profile located in the spike region comprise a tangent having a slope with an absolute value that is 20 MPa/micrometer or greater, and all points of the stress profile located in the tail region comprise a tangent having a slope with an absolute value that is less than 20 MPa/micrometer.

46. A consumer electronic product comprising:
a housing having a front surface, a back surface, and side surfaces;
electrical components at least partially within the housing, the electrical components comprising at least a controller, a memory, and a display, the display at or adjacent the front surface of the housing; and
a cover disposed over the display;
wherein at least a portion of at least one of the housing and the cover comprises the glass-based article of claim 35.

47. A method of manufacturing a glass-based article comprising:
exposing a glass-based substrate that comprises sodium oxide and lithium oxide in a base composition, the glass-based substrate having opposing first and second surfaces defining a substrate thickness (t), to an ion exchange treatment to form the glass-based article, the ion exchange treatment comprising:
a first bath comprising a potassium salt and a sodium salt and a lithium salt; and
a second bath comprising a potassium salt, a sodium salt, and optionally a lithium salt;
wherein the one of the following is met:
t is less than or equal to 0.74 mm;
the substrate comprises a composition wherein a molar ratio of Na₂O to Li₂O in the lithium-based aluminosilicate composition is less than or equal to 1.3; or
t is less than or equal to 0.74 mm and the substrate comprises a composition wherein a molar ratio of Na₂O to Li₂O in the lithium-based aluminosilicate composition is greater than or equal to 1.3;
wherein the glass-based article comprises a stress profile comprising:
a spike region extending from the first surface and comprising a spike depth of layer (DOLₛₚ) located at a depth of greater than or equal to 0.010·t; and
a maximum central tension (CTₘₐₓ) of greater than or equal to 50 MPa.

48. The method of claim 47, wherein after exposure to the first bath, a value of weight gain of the glass-based substrate is in a range of greater than or equal to −0.35% to less than or equal to 0.1(1+0.02/0%, wherein t is measured in millimeters.

49. The method of claim 47, wherein content of the sodium salt in the second bath is greater that content of the sodium salt in the first bath.

50. The method of claim 47, wherein the ion exchange treatment further comprises a third bath comprising a potassium salt and a sodium salt wherein content of the potassium salt in the third bath is greater than or equal to 90% by weight.

51. The method of claim 47, wherein the first bath comprises: 50-60 wt. % NaNO₃, 10-20 wt. % LiNO₃, and 20-35 wt. % KNO₃, wherein content of the NaNO₃, LiNO₃, and KNO₃ totals 100%, and the glass substrate comprises a base composition having a molar ratio of Na₂O to Li₂O of greater than or equal to 1.3.

52. The method of claim 47, wherein the first bath comprises: 1-3 wt. % NaNO₃, 6-10 wt. % LiNO₃, and 88-90 wt. % KNO₃, wherein content of the NaNO₃, LiNO₃, and KNO₃ totals 100%, and the glass substrate comprises a base composition having a molar ratio of Na₂O to Li₂O of less than or equal to 1.3.
